(19) United States
(12) Patent Application Publication
(10) Pub. No.: US 2017/0223843 A1
(43) Pub. Date: Aug. 3, 2017

(54) MULTILAYER CURABLE RESIN FILM, PREPREG, LAMINATE, CURED PRODUCT, COMPOSITE, AND MULTILAYER CIRCUIT BOARD

(71) Applicant: ZEON CORPORATION, Tokyo (JP)

(72) Inventors: Osamu Kawakami, Tokyo (JP); Shigeru Fujita, Tokyo (JP)

(73) Assignee: ZEON CORPORATION, Tokyo (JP)

(21) Appl. No.: 15/123,527

(22) PCT Filed: Mar. 4, 2015
(86) PCT No.: PCT/JP2015/056328

§ 371 Date: Sep. 2, 2016

(30) Foreign Application Priority Data
Mar. 7, 2014 (JP) 2014-044678

(51) Int. Cl. H05K 3/46; B32B 27/32; B32B 27/12; H05K 3/22; H05K 1/11; H05K 3/00; H05K 3/40; C23C 18/31; B32B 37/18

(52) U.S. Cl. CPC H05K 3/4644; C23C 18/31; B32B 27/32; B32B 27/12; B32B 37/182; H05K 1/115; H05K 3/4611; H05K 3/0026; H05K 3/4076; H05K 3/22; B32B 2457/08; H05K 2203/107

(57) ABSTRACT

A multilayer curable resin film comprising a first resin layer comprising a first curable resin composition including a polyphenylene ether oligomer (A1) with an end modified by an aromatic vinyl group and a curing agent (A2) and a second resin layer comprising a second curable resin composition including an alicyclic olefin polymer (B1) and a curing agent (B2), a prepreg comprised of this including a fiber substrate, and a laminate, cured product, composite, and multilayer circuit board obtained using these are provided.

### TECHNICAL FIELD

The present invention relates to a multilayer curable resin film, prepreg, laminate, cured product, composite, and multilayer circuit board.

### BACKGROUND ART

Along with the pursuit of electronic equipment of smaller sizes, greater functions, faster communication speeds, etc., further higher densities of the circuit boards used for the electronic equipment have been sought. To meet these demands for higher densities, circuit boards have been made multilayered. Such a multilayer circuit board, for example, is formed by using an internal layer board comprised of an electrical insulating layer and conductor pattern layers formed on its surfaces, stacking an electrical insulating layer over that, forming a conductor pattern layer on top of the electrical insulating layer, and further repeating this stacking of the electrical insulating layer and formation of the conductor pattern layer.

As the material for forming an electrical insulating layer of such a multilayer circuit board, in general a ceramic or heat curable resin is used. For example, as a heat curable resin, an epoxy resin, fluorine-based resin, polyolefin-based resin, polystyrene-based resin, polyphenylene ether-based resin, etc. have been proposed.

As a resin material using a polyphenylene ether-based resin as one example of a resin material for forming such an electrical insulating layer, for example, Patent Document 1 discloses a curable resin composition comprising a polyphenylene ether oligomer with an end modified by an aromatic vinyl group and a styrene-based thermoplastic elastomer with a weight average molecule weight of 1,0000 to 300,000 as essential ingredients wherein a weight ratio of the polyphenylene ether oligomer with an end modified by an aromatic vinyl group and the styrene-based thermoplastic elastomer is 20:80 to 95:5.

### RELATED ART

### Patent Documents

Patent Document 1: Japanese Patent No. 4867217

### SUMMARY OF THE INVENTION

### Problem to be Solved by the Invention

However, when the present inventors studied this, it was difficult to raise the roughness of the surface when using the curable resin composition described in this Patent Document 1 to form an electrical insulating layer of a multilayer circuit board. Therefore, when forming conductor patterns on the surface of an electrical insulating layer by electroless plating etc., the conductor patterns were insufficiently adhered and could not sufficiently meet the requirements for higher performance of the multilayer circuit board.

An object of the present invention is to provide a multilayer curable resin film able to form an electrical insulating layer excellent in electrical characteristics and mechanical characteristics and enabling formation of plated conductors by electroless plating with a high adhesion, a prepreg comprised of this including a fiber substrate, and a laminate, cured product, composite, and multilayer circuit board obtained using these.

### Means for Solving the Problem

The present inventors engaged in intensive research to achieve the above object and as a result discovered that the above object can be achieved by making the multilayer curable resin film for forming the electrical insulating layer one comprised of a first resin layer comprising a first curable resin composition including a polyphenylene ether oligomer with an end modified by an aromatic vinyl group and a curing agent and a second resin layer comprising a second curable resin composition including an alicyclic olefin polymer and a curing agent and thereby completed the present invention.

That is, according to the present invention, there are provided:

[1] a multilayer curable resin film comprising a first resin layer comprising a first curable resin composition including a polyphenylene ether oligomer with an end modified by an aromatic vinyl group (A1) and a curing agent (A2) and a second resin layer comprising a second curable resin composition including an alicyclic olefin polymer (B1) and a curing agent (B2),
[2] the multilayer curable resin film according to [1] wherein the alicyclic olefin polymer (B1) is an alicyclic olefin polymer having a polar group,
[3] the multilayer curable resin film according to [1] or [2] wherein the first curable resin composition further comprises an elastomer (A3),
[4] the multilayer curable resin film according to any one of [1] to [3] wherein the first curable resin composition further comprises a polymer (A4) having a triazine structure,
[5] the multilayer curable resin film according to any one of [1] to [4] wherein the second curable resin composition further comprises an inorganic filler (B3),
[6] the multilayer curable resin film according to any one of [1] to [5] further comprising a support film on the surface of the second resin layer at the opposite side to the surface where the first resin layer is laminated,
[7] a method of production of a multilayer curable resin film according to any one of [1] to [6] comprising a step of forming the second resin layer by coating, spraying, or flow casting the second curable resin composition on a substrate and a step of forming the first resin layer by coating, spraying, or flow casting the first curable resin composition on the second resin layer,
[8] a method of production of a multilayer curable resin film according to any one of [1] to [6] comprising a step of forming the first resin layer by coating, spraying, or flow casting the first curable resin composition on a substrate, a step of forming the second resin layer by coating, spraying, or flow casting the second curable resin composition on another substrate, and a step of laminating the respectively formed first resin layer and second resin layer on separate substrates,
[9] a prepreg comprising a multilayer curable resin film according to any one of [1] to [6] including a fiber substrate,
[10] a laminate obtained by laminating a multilayer curable resin film according to any one of [1] to [6] or a prepreg according to [9] on a substrate,
[11] a cured product obtained by curing a multilayer curable resin film according to any one of [1] to [6], a prepreg according to [9], or a laminate according to [10].
[12] a composite obtained by forming a conductor layer on a surface of a cured product according to claim [11],
[13] a multilayer circuit board comprising a cured product according to [11] or a composite according to [12] and a board having an electrical insulating layer and formed with a conductor circuit layer on one or both surfaces of the electrical insulating layer, and
[14] a method of production of a multilayer circuit board comprising a step of laminating a multilayer curable resin film according to [6] on a board having an electrical insulating layer and formed with a conductor circuit layer on one or both surfaces of the electrical insulating layer so that the board and the first resin layer of the multilayer curable resin film contact each other, a step of curing the multilayer curable resin film to obtain a cured product, a step of irradiating the cured product with a laser to form a via hole or through hole, a step of peeling off the support film, and a step of plating the surfaces of the via hole or through hole and cured product to form a conductor layer.

### Effects of the Invention

According to the present invention, there are provided a multilayer curable resin film able to form an electrical insulating layer excellent in electrical characteristics and mechanical characteristics and enabling formation of plated conductors by electroless plating with a high adhesion, a prepreg comprised of this including a fiber substrate, and a laminate, cured product, composite, and multilayer circuit board obtained using these.

### DESCRIPTION OF EMBODIMENTS

(Multilayer Curable Resin Film)

The multilayer curable resin film of the present invention comprises a first resin layer comprising a first curable resin composition including a polyphenylene ether oligomer (A1) with an end modified by an aromatic vinyl group and a curing agent (A2) and a second resin layer comprising a second curable resin composition including an alicyclic olefin polymer (B1) and a curing agent (B2).

First, the first curable resin composition for forming the first resin layer will be explained.

(First Curable Resin Composition)

The first curable resin composition is a resin composition including a polyphenylene ether oligomer (A1) with an end modified by an aromatic vinyl group and a curing agent (A2). Note that, the first resin layer formed by the first curable resin composition is not particularly limited, but can be suitably used as an adhesive layer for adhesion with a conductor layer. In the present invention, by using a first curable resin composition having the above configuration to form an adhesive layer (first resin layer), it is possible to make the obtained electrical insulating layer one excellent in electrical characteristics and mechanical characteristics.

[Polyphenylene Ether Oligomer (A1) with End Modified by Aromatic Vinyl Group]

The polyphenylene ether oligomer (A1) with an end modified by an aromatic vinyl group used in the present invention (below, suitably abbreviated as the “polyphenylene ether oligomer (A1)”) is not particularly limited so long as a compound in which at least one of the polymerization ends of the polyphenylene ether oligomer is modified by an aromatic vinyl group, but a compound represented by the following general formula (1) can be suitably used. By using the polyphenylene ether oligomer (A1) as the resin component for forming the first resin layer, the obtained electrical insulating layer can be made particularly excellent in electrical characteristics.

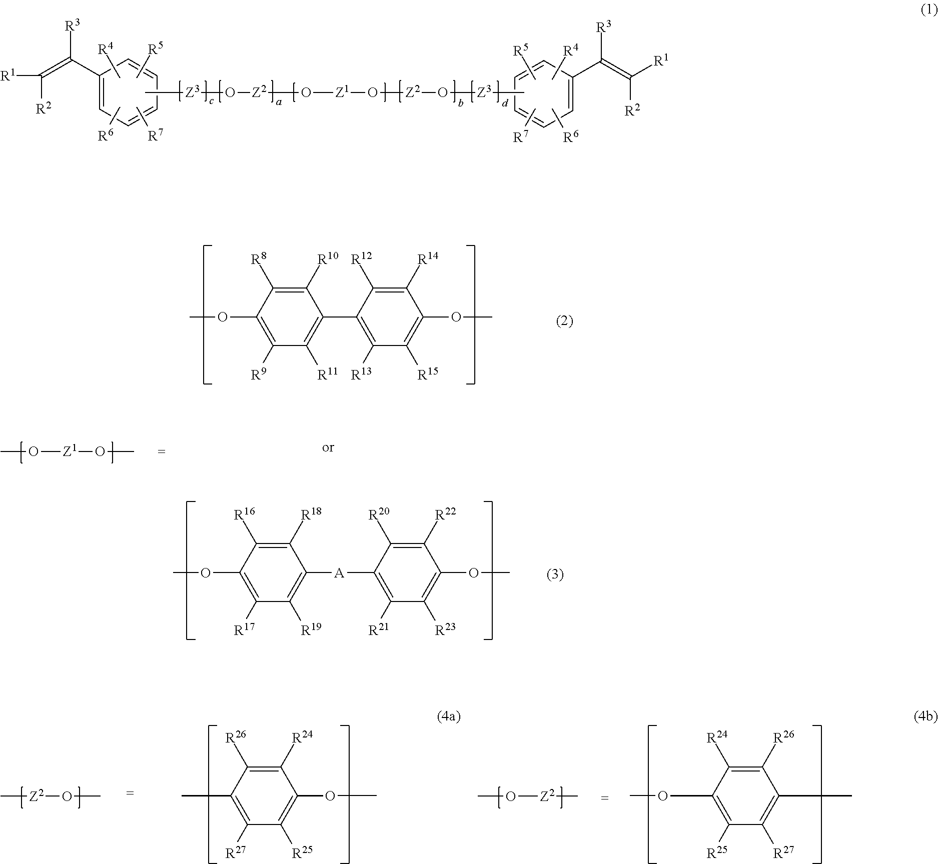

In the general formula (1), R¹ to R⁷ mutually independently are a hydrogen atom, halogen atom, alkyl group, halogenated alkyl group, or aryl group, preferably a hydrogen atom.

In the general formula (1), —[O—Z¹—O]— is one type of structure or two or more types of structures represented by the general formula (2) or the general formula (3). In the general formulas (2) and (3), R⁸, R⁹, R¹⁰, R¹⁴, R¹⁵, R¹⁶, R¹⁷, R²², and R²³ are mutually independently a halogen atom or an alkyl group having six or less carbon atoms or a phenyl group, and an alkyl group having three or less carbon atoms is preferable. Further, in the general formulas (2) and (3), R¹¹, R¹², R¹³, R¹⁸, R¹⁹, R²⁰, and R²¹ are mutually independently a hydrogen atom, halogen atom, or an alkyl group having six or less carbon atoms or a phenyl group, and a hydrogen atom or an alkyl group having three or less carbon atoms is preferable. Furthermore, in the general formula (3), “A” is a linear, branched, or cyclic hydrocarbon having 20 or less carbon atoms.

In particular, in the general formula (1), as —[O—Z¹—O]—, one type of structure or two or more types of structures represented by the following general formula (4) or the following general formula (5) are more preferable.

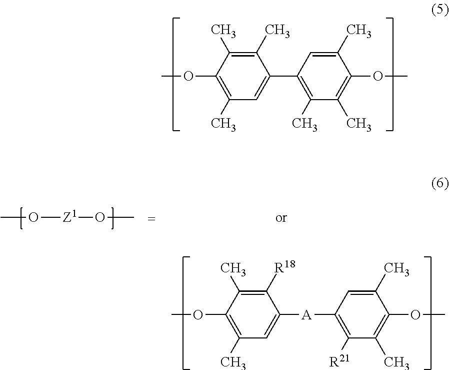

(In the general formula (5), R¹⁸ and R²¹ are a hydrogen atom or methyl group, while “A” is a linear, branched, or cyclic hydrocarbon having 20 or less carbon atoms.)

Further, in the general formula (1), —[Z²—O]— is comprised of one type of structure represented by the general formula (4a) or two or more types of structures represented by the general formula (4a) randomly arranged. Similarly, in the general formula (3), —[O—Z²]— is one type of structure represented by the general formula (4b) or two or more types of structures represented by the general formula (4b) randomly arranged. In the general formulas (4a) and (4b), R²⁴ and R²⁵ are mutually independently a halogen atom or an alkyl group having six or less carbon atoms or a phenyl group, while R²⁶ and R²⁷ mutually independently are a hydrogen atom, halogen atom, or an alkyl group having six or less carbon atoms or a phenyl group.

In particular, in the general formula (1), as —[Z²—O]—, a structure represented by the following general formula (7a), a structure represented by the following general formula (8a), or a structure including a structure represented by the following general formula (7a) and a structure represented by the following general formula (8a) randomly arranged is more preferable. Similarly, in the general formula (1), as —[O—Z²]—, a structure represented by the following general formula (7b), a structure represented by the following general formula (8b), or a structure including a structure represented by the following general formula (7b) and a structure represented by the following general formula (8b) randomly arranged is more preferable.

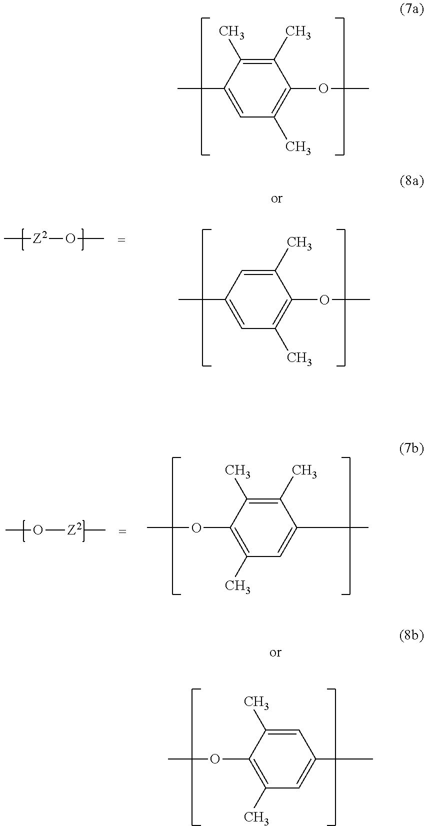

Further, in the general formula (1), “a” and “b” are integers of 0 to 30, where at least one is not 0, and “c” and “d” are 0 or 1.

The method of producing the compound represented by the general formula (1) is not particularly limited, but the compound may be obtained by causing a compound represented by the following general formula (9) to react with a haloalkyl group-containing aromatic vinyl compound such as chloromethylstyrene in the presence of an alkali catalyst such as sodium hydroxide, potassium carbonate, sodium ethoxide, etc. and, if necessary, using a phase transfer catalyst such as benzyl tri-n-butylammonium bromide and 18-crown-6-ether. Further, the compound represented by following general formula (9) can be obtained by the method of copolymerizing a divalent phenol and monovalent phenol described in Japanese Patent Publication No. 2003-12796A or Japanese Patent Publication No. 2003-212990A.

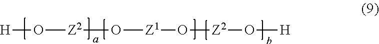

(In the general formula (9), —[O—Z¹—O]—, —[Z²—O]—, “a”, and “b” are similar to the general formula (1))

The polyphenylene ether oligomer (A1) used in the present invention has a number average molecular weight (Mn) of preferably 500 to 3,000. If the number average molecular weight (Mn) is too small, the multilayer curable resin film of the present invention tends to become tacky and sometimes becomes inferior in processability, while if too large, the solubility in a solvent ends up decreasing and the processability when preparing the first curable resin composition ends up becoming inferior.

[Curing Agent (A2)]

The curing agent (A2) used in the present invention is not particularly limited so long as a compound able to cure the above-mentioned polyphenylene ether oligomer (A1) by heating, light, etc., but is preferably a compound able to polymerize the vinyl group of the above-mentioned polyphenylene ether oligomer (A1). Specifically, a radical generator is preferable.

As the radical generator, an organic peroxide, azo compound, etc. may be mentioned, but from the viewpoint of the reactivity, an organic peroxide is preferable.

As the organic peroxide, a dialkyl peroxide such as di-o-methylbenzoyl peroxide, di-p-methylbenzoyl peroxide, dicumyl peroxide, 2,5-dimethyl-2,5-di(t-butylperoxy)hexane, 1,3-bis(t-butylperoxyisopropyl)benzene, t-butylcumylperoxide, di-t-butyl peroxide, and 2,5-dimethyl-2,5-di(t-butylperoxy)hexine-3; a hydroperoxide such as p-methane hydroperoxide, diisopropylbenzene hydroperoxide, 1,1,3,3-tetramethylbutyl hydroperoxide, cumen hydroperoxide, and t-butyl hydroperoxide; a diacyl peroxide such as diisobutyl peroxide, dilauroyl peroxide, di(3,5,5-trimethylhexanoyl) peroxide, di(3-methylbenzoyl)peroxide, and dibenzoyl peroxide; a peroxy dicarbonate such as di-n-propylperoxy dicarbonate, diisopropylperoxy dicarbonate, di(4-t-butylcyclohexyl)peroxy carbonate, and di(2-ethylhexyl)peroxy dicarbonate; a peroxy ester such as t-butylperoxy neodecanoate, t-hexylperoxy neodecanoate, 1,1,3,3-tetramethylbutylperoxy neodecanoate, cumylperoxy neodecanoate, t-butylperoxy necheptanoate, t-butylperoxy-2-ethyl hexanoate, t-hexylperoxy-2-ethyl hexanoate, 2,5-dimethyl-2,5-di(2-ethylhexanoylperoxy)hexane, t-butyl permaleic acid, t-butylperoxy-3,5,5-trimethyl hexanoate, t-butylperoxyisopropyl monocarbonate, t-hexylperoxyisopropyl monocarbonate, t-butylperoxy laurate, t-hexylperoxy benzoate, 2,5-dimethyl-2,5-di(benzoylperoxy)hexane, t-butylperoxy acetate, and t-butylperoxy benzoate; a peroxyketal such as n-butyl-4,4-di-(t-butylperoxy)valerate, 2,2-di-(t-butylperoxy)butane, 2,2-di(4,4-di-(t-butylperoxy)cyclohexyl)propane, 1,1-di(t-hexylperoxy)-3,5,5-trimethylcyclohexane, 1,1-di(t-butylperoxy)-2-methylcyclohexane, 1,1-di(t-butylperoxy)cyclohexane, and 1,1-di(t-hexylperoxy)cyclohexane; etc. may be mentioned, but even among these organic peroxides, due to their high half life temperature, dialkyl peroxide or hydroperoxide is preferable. Further, these organic peroxides may be used as single types alone or as two types or more combined.

In the first curable resin composition used in the present invention, the amount of the curing agent (A2) is preferably 0.01 to 10 parts by weight with respect to 100 parts by weight of the polyphenylene ether oligomer (A1), more preferably 0.02 to 1 part by weight, still more preferably 0.05 to 0.5 part by weight. By making the amount of the curing agent (A2) the above range, the obtained electrical insulating layer can be made better in electrical characteristics.

[Elastomer (A3)]

Further, the first curable resin composition used in the present invention preferably contains, in addition to the above-mentioned polyphenylene ether oligomer (A1) and curing agent (A2), an elastomer (A3). By including an elastomer (A3), the obtained electrical insulating layer can be made more excellent in mechanical characteristics (specifically, tensile strength and tensile elasticity).

As the elastomer (A3), a rubber and thermoplastic elastomer may be mentioned. While not particularly limited, a high molecular weight compound having a weight average molecule weight (Mw) of 10,000 or more is preferable. By using the elastomer (A3), the obtained electrical insulating layer can be made excellent in mechanical characteristics.

As specific examples of the elastomer (A3), a random or block copolymer of an aromatic vinyl compound and conjugated diene compound such as a styrene-butadiene random copolymer (SBR), styrene-butadiene-styrene block copolymer (SBS), styrene-isoprene-styrene block copolymer (SIS), and styrene(butadiene/isoprene)styrene block copolymer and their partial or full hydrogenates; an acrylonitrile-butadiene copolymer and its partial or full hydrogenates; etc. may be mentioned. Here, “partial or full hydrogenates” is the general term for partial hydrogenates obtained by hydrogenating only part of the unsaturated bonds of the copolymer and full hydrogenates obtained by hydrogenating all of the unsaturated bonds including aromatic rings of the copolymer. The elastomer (A3) may be used alone or two or more types may be jointly used. Among these, from the viewpoint of the good solubility with the polyphenylene ether oligomer (A1) and higher effect of improvement of the mechanical characteristics of the obtained electrical insulating layer, a copolymer of an aromatic vinyl compound and conjugated diene compound and its partial or full hydrogenate are preferable, a block copolymer of an aromatic vinyl compound and a conjugated diene compound and its partial or full hydrogenate are more preferable, and a styrene-isoprene-styrene block copolymer (SIS) and its partial or full hydrogenate are still more preferable.

The weight average molecule weight (Mw) of the elastomer (A3) is not particularly limited, but is preferably 10,000 to 500,000, more preferably 12,000 to 300,000. By using as the elastomer (A3) one having a weight average molecule weight (Mw) in the above range, the obtained electrical insulating layer can be further enhanced in effect of improvement of the electrical characteristics.

In the first curable resin composition used in the present invention, the amount of the elastomer (A3) is preferably 10 to 70 wt % in range with respect to a total 100 wt % of the above-mentioned polyphenylene ether oligomer (A1) and elastomer (A3), more preferably 15 to 60 wt % in range, still more preferably 20 to 50 wt % in range. By making the amount of the elastomer (A3) the above range, the obtained electrical insulating layer can be further enhanced in effect of improvement of the electrical characteristics.

Further, when mixing the elastomer (A3) into the first curable resin composition used in the present invention, the amount of the above-mentioned curing agent (A2) is preferably made the following range with respect to the total amount of the polyphenylene ether oligomer (A1) and the elastomer (A3). That is, the amount of the curing agent (A2) is preferably made 0.01 to 1 part by weight in range with respect to a total 100 parts by weight of the polyphenylene ether oligomer (A1) and the elastomer (A3), more preferably 0.02 to 0.3 part by weight in range.

[Polymer (A4) Having Triazine Structure]

Further, the first curable resin composition used in the present invention preferably further has a polymer (A4) having a triazine structure mixed into it. By further including the polymer (A4) having a triazine structure, the obtained electrical insulating layer can be made excellent in adhesion with respect to the conductor layer comprised of metal foil etc.

The polymer (A4) having a triazine structure used in the present invention (below, suitably referred to as “triazine structure-containing polymer (A4)”) is a polymer having a triazine structure and is preferably a polymer having a triazine structure at a side chain. Note that, in the present invention, “having a triazine structure at a side chain” means the state not where the triazine structure forms part of the main chain of the polymer, but where the triazine structure is bonded to the main chain of the polymer directly or through another group. Further, the polymer having a triazine structure at a side chain may have a ring-shaped main chain structure. In this case as well, the ring-shaped main chain structure has a structure where the triazine structure will substantially not be taken into the ring shape of the main chain structure.

Further, as the polymer (A4) having the triazine structure used in the present invention, an oligomer with a relatively low polymerization degree (for example, oligomer with polymerization degree of 3 or so or 3 or more) is included.

The triazine structure-containing polymer (A4) is not particularly limited, but from the viewpoint that the effect of improvement of adhesion to a conductor layer made of a metal foil becomes more remarkable, a triazine structure-containing polymer (A4a) obtained by causing a condensation reaction between a compound represented by the following general formula (10a) or (10b) and a compound represented by the following general formula (11a) or (11b) is preferable.

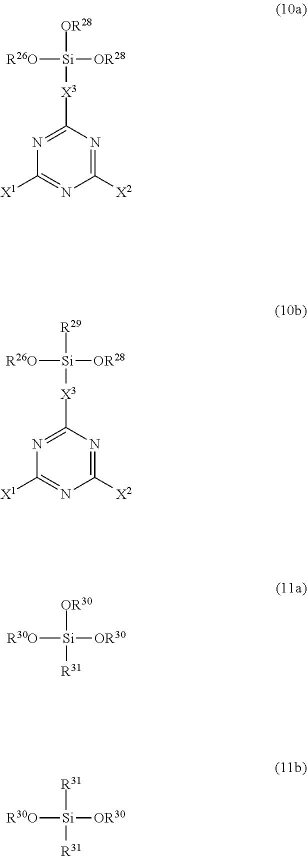

In the general formulas (10a) and (10b), R²⁸ is a hydrogen atom or an alkyl group having 1 to 6 carbon atoms, preferably an alkyl group having 1 to 4 carbon atoms. R²⁹ is an alkyl group having 1 to 6 carbon atoms, alkenyl group having 2 to 6 carbon atoms, cycloalkyl group having 3 to 14 carbon atoms, cycloalkenyl group having 3 to 14 carbon atoms, or aryl group having 6 to 12 carbon atoms which are substituted or unsubstituted. Further, X¹ and X² respectively independently are a group represented by —H, —OR³², —SR³³, or NR³⁴R³⁵ (R³² to R³⁵ respectively independently are a hydrogen atom, an alkyl group having 1 to 12 carbon atoms, or aryl group having 6 to 12 carbon atoms which are substituted or unsubstituted), preferably a group represented by —NR³⁴R³⁵. Further, X³ is a chemical single bond or a group represented by —R³⁶—O—R³⁷—, —R³⁸—S—R³⁹, or —R⁴⁰—O(═O)—OR⁴¹— (R³⁶ to R⁴¹ respectively independently are a substituted or unsubstituted alkylene group having 1 to 6 carbon atoms), preferably a group represented by —R³⁸—S—R³⁹—.

On the other hand, in the general formulas (11a) and (11b), R³⁰ is a hydrogen atom or an alkyl group having 1 to 6 carbon atoms, preferably an alkyl group having 1 to 4 carbon atoms. R³¹ is an alkyl group having 1 to 6 carbon atoms, alkenyl group having 2 to 6 carbon atoms, cycloalkyl group having 3 to 14 carbon atoms, cycloalkenyl group having 3 to 16 carbon atoms, or aryl group having 6 to 14 carbon atoms which are substituted or unsubstituted.

The triazine structure-containing polymer (A4a) used in the present invention, as explained above, is a compound obtained by a condensation reaction of the compound represented by the general formula (10a) or (10b) and a compound represented by the general formula (11a) or (11b). The units based on the compound represented by the general formula (10a) or (10b) exhibit the action of improving the adhesion strength with a conductor layer by the effect of the triazine structure while, further, the units based on the compound represented by the general formula (11a) or (11b) have the action of improving the compatibility with the polyphenylene ether oligomer (A1). By mixing in a triazine structure-containing polymer (A4a) having such a structure, the obtained electrical insulating layer can be further improved in adhesion with a conductor layer.

When obtaining the triazine structure-containing polymer (A4a) used in the present invention, the method of causing a condensation reaction between the compound represented by the general formula (10a) or (10b) and the compound represented by the general formula (11a) or (11b) is not particularly limited, but, for example, the method of hydrolyzing the —OR²⁸ group of the compound represented by the general formula (10a) or (10b) and the —OR²⁹ group of the compound represented by the general formula (11a) or (11b) and causing dehydration and condensation of the obtained hydrolyzate of the compound represented by the general formula (10a) or (10b) and hydrolyzate of the compound represented by the general formula (11a) or (11b) may be mentioned. At this time, the hydrolysis reaction and the dehydration and condensation reaction may be performed in accordance with known methods.

Further, as the compound represented by the general formula (10a) or (10b), a plurality of compounds in which R²⁹ or any of X¹, X², and X³ differ from each other may be used. In this case, as the units based on the compound represented by the general formula (10a) or (10b), a plurality of units in which any of X¹, X², and X³ differ from each other may be introduced into the triazine structure-containing polymer (A4a). Similarly, as the compound represented by the general formula (11a) or (11b), a plurality of compounds in which R³¹ differs from each other may be used. In this case, as the units based on the compound represented by the general formula (11a) or (11b), a plurality of units in which R³¹ differs from each other may be introduced into the triazine structure-containing polymer (A4a).

A triazine structure-containing polymer (A4a) obtained by causing a condensation reaction of a compound represented by the general formula (10a) or (10b) and a compound represented by the general formula (11a) or (11b) in this way, for example, may be considered to have the following structural units. That is, one having units represented by the following general formula (12) as units based on the compound represented by the general formula (10a) or (10b) and units represented by the following general formula (13) as units based on the compound represented by the general formula (11a) or (11b) may be considered.

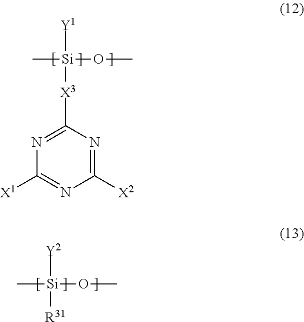

Here, in the general formula (12), X¹ to X³ are similar to the general formulas (10a) and (10b), Y¹ is a group represented by R²⁹ (R²⁹ is similar to the general formulas (10a) and (10b)), —OH, or —OR²⁸ (R²⁸ is similar to the general formulas (10a) and (10b)), units represented by the general formula (12), or units represented by the general formula (13). That is, in the units represented by the above general formula (12), at least two of the three or two —OR²⁸ groups which were present in the compound represented by the above general formula (10a) or (10b) participate in the condensation reaction and form condensed structures. On the other hand, as remaining one —OR²⁸ group, it is considered that a part of this does not participate in the condensation reaction but remains as a group represented by —OH or —OR²⁸, and the remaining part of this participates in the condensation reaction so as to form a condensed structure together with still other units (that is, units represented by the above general formula (12) and units represented by the above general formula (13)).

Further, in the general formula (13), R³¹ is similar to the general formulas (11a) and (11b), and Y² is a group represented by R³¹ (R³¹ is similar to the general formulas (11a) and (11b)), —OH, or —OR³⁰ (R³⁰ is similar to the general formulas (11a) and (11b)), a unit represented by the general formula (12), or a unit represented by the general formula (13). That is, in the units represented by the above general formula (13) as well, at least two of the three or two —OR³⁰ groups which were present in the compound represented by the above general formula (11a) or (11b) participate in the condensation reaction and form condensed structures. On the other hand, as remaining one —OR³⁰ group, it is considered that a part of this does not participate in the condensation reaction but remains as a group represented by —OH or —OR³⁰, and the remaining part of this participates in the condensation reaction so as to form a condensed structure together with still other units (that is, units represented by the above general formula (12) and units represented by the above general formula (13)).

In the triazine structure-containing polymer (A4a) used in the present invention, the ratio of the units based on the compound represented by the general formula (10a) or (10b) and the units based on the compound represented by the general formula (11a) or (11b) may be suitably set according to the targeted adhesion with the conductor layer and compatibility with the polyphenylene ether oligomer (A1), but is a molar ratio of “units based on compound represented by general formula (10a) or (10b): units based on compound represented by general formula (11a) or (11b)” of preferably 0.1:99.9 to 20:80, more preferably 5:95 to 15:85. Note that, the ratio of the units based on the compound represented by the general formula (10a) or (10b) and the units based on the compound represented by the general formula (11a) or (11b) can be controlled by adjusting the ratio between the compound represented by the general formula (10a) or (10b) and the compound represented by the general formula (11a) or (11b) which are used for the condensation reaction.

Further, as the triazine structure-containing polymer (A4), instead of the above-mentioned triazine structure-containing polymer (A4a) or together with the triazine structure-containing polymer (A4a), a triazine structure-containing polymer (A4b) having units represented by the following general formula (14) and units represented by the following general formula (15) may be used.

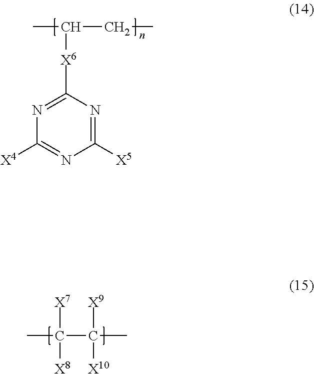

In the general formula (14), X⁴ and X⁵ respectively independently are a group represented by —H, —OR⁴², —SR⁴³, or NR⁴⁴R⁴⁵ (R⁴² to R⁴⁵ respectively independently are a hydrogen atom, or an alkyl group having 1 to 12 carbon atoms, or aryl group having 6 to 12 carbon atoms which are substituted or unsubstituted), preferably a group represented by —NR⁴⁴R⁴⁵. Further, in the general formula (14), X⁶ is a chemical single bond or group represented by —R⁴⁶—O—R⁴⁷—, —R⁴⁸—S—R⁴⁹—, or R⁵⁰—C(═O)—OR⁵¹— (R⁴⁶ to R⁵¹ respectively independently are a substituted or unsubstituted alkylene group having 1 to 6 carbon atoms), preferably a chemical single bond. Note that, the triazine structure-containing polymer (A4a) may contain, as the units represented by the general formula (14), a plurality of units in which any of X⁴, X⁵, and X⁶ differ from each other.

On the other hand, in the general formula (15), X⁷ to R¹⁰ respectively independently are a group represented by —H, —R⁵², —OR⁵³, —O—C(═O)—R⁵⁴, —C(═O)—OR⁵⁵, or O—C(═O)—OR⁵⁶ (R⁵² to R⁵⁶ respectively independently are a hydrogen atom, or an alkyl group having 1 to 6 carbon atoms, alkenyl group having 2 to 6 carbon atoms, cycloalkyl group having 3 to 14 carbon atoms, cycloalkenyl group having 3 to 14 carbon atoms, or aryl group having 6 to 12 carbon atoms which are substituted or unsubstituted). Note that, the triazine structure-containing polymer (A4b) used in the present invention may contain a plurality of units in which any of X⁷ to X¹⁰ differs from each other as the units represented by the general formula (15).

The triazine structure-containing polymer (A4b) used in the present invention, as explained above, has units represented by the general formula (14) and units represented by the general formula (15).

In the same way as the above explained triazine structure-containing polymer (A4a), the units represented by the general formula (14) exhibit the action of improving the adhesion strength with a conductor layer by the effect of the triazine structure while, further, the units represented by the general formula (15) have the action of improving the compatibility with the polyphenylene ether oligomer (A1). Further, by this, the obtained electrical insulating layer can be more suitably improved in adhesion with a conductor layer.

In the triazine structure-containing polymer (A4b) used in the present invention, the ratio of the units represented by the general formula (14) and the units represented by the general formula (15) may be suitably set according to the targeted adhesion with the conductor layer and compatibility with the polyphenylene ether oligomer (A1), but as a molar ratio of “units represented by general formula (14): units represented by general formula (15)” is preferably 0.01:99.99 to 20:80, more preferably 2:98 to 5:95. Further, the triazine structure-containing polymer (A4b) has a weight average molecule weight of preferably 1,000 to 100,000, more preferably 2,000 to 12,000.

The triazine structure-containing polymer (A4b) usually can be produced by copolymerization of a compound represented by the following general formula (16) and a compound represented by the following general formula (17). The type of the copolymerization may be either block copolymerization and random copolymerization, but from the viewpoint of the action and effect becoming more remarkable, block copolymerization is preferable. Note that, when including, as the units represented by the general formula (14), a plurality of units in which any of X⁴, X⁵, and X⁶ differ from each other, it is possible to use a corresponding plurality of compounds as the compound represented by the following general formula (16). Similarly, when including a plurality of units in which any one X⁷ to X¹⁰ differ from each other as the units represented by the general formula (15), it is possible to use a corresponding plurality of compounds as the compound represented by the following general formula (17).

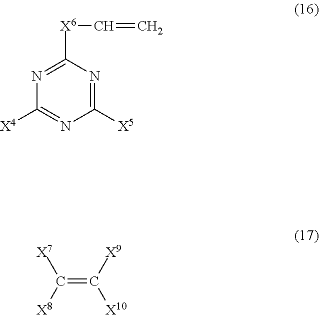

(In the general formulas (16) and (17), X⁴ to X¹⁰ are similar to the general formulas (14) and (15).)

In the first curable resin composition used in the present invention, the amount of the triazine structure-containing polymer (A4) is preferably 0.1 to 40 parts by weight with respect to 100 parts by weight of the polyphenylene ether oligomer (A1), more preferably 0.5 to 20 parts by weight, still more preferably 1 to 15 parts by weight. Further, when mixing the elastomer (A3) into the first curable resin composition used in the present invention, the amount of the triazine structure-containing polymer (A4) is preferably 0.05 to 20 parts by weight in range with respect to the total 100 parts by weight of the polyphenylene ether oligomer (A1) and elastomer (A3), more preferably 0.1 to 10 parts by weight in range. If the amount of the triazine structure-containing polymer (A4) is too small, the effect of improvement of adhesion with the conductor layer becomes difficult to obtain, while if the amount is too large, the adhesion with the conductor layer is liable to fall or the electrical characteristics or storage stability is liable to fall.

[Other Ingredients]

The first curable resin composition used in the present invention may suitably contain other ingredients such as described below in addition to the above ingredients in a range not inhibiting the expression of the effect of the present invention.

That is, the first curable resin composition used in the present invention may have an inorganic filler mixed into it.

The inorganic filler is not particularly limited, but for example calcium carbonate, magnesium carbonate, barium carbonate, zinc oxide, titanium oxide, magnesium oxide, magnesium silicate, calcium silicate, zirconium silicate, hydrated alumina, magnesium hydroxide, aluminum hydroxide, barium sulfate, silica, talc, clay, etc. may be mentioned. Among these, from the viewpoint of the excellent electrical characteristics, silica is preferable. Note that, the inorganic filler may be one treated in advance on its surface by a silane coupling agent etc. An inorganic filler which makes the obtained electrical insulating layer low in linear expansion by inclusion is preferable. The average particle size of the inorganic filler is not particularly limited, but is preferably 0.1 to 10 μm, more preferably 0.2 to 2 μm, particularly preferably 0.25 to 1 μm.

In the first curable resin composition used in the present invention, the amount of the inorganic filler is not particularly limited, but is preferably 30 to 90 wt % by conversion to solid content, more preferably 45 to 85 wt %, still more preferably 50 to 80 wt %.

Further, the first curable resin composition used in the present invention may contain an alicyclic olefin polymer having a polar group. As the alicyclic olefin polymer having a polar group, one similar to the alicyclic olefin polymer (B1) used for the later explained second curable resin composition and having a polar group may be used without restriction.

Further, the first curable resin composition used in the present invention may suitably contain, for the purpose of improving the flame retardance of the obtained electrical insulating layer, for example, a flame retardant mixed into general resin compositions for forming electrical insulating films such as a halogen-based flame retardant or phosphoric acid-based flame retardant.

Furthermore, the first curable resin composition used in the present invention may suitably contain, as desired, known ingredients such as a flame retardant aid, heat resistance stabilizer, weather resistance stabilizer, antiaging agent, UV absorbent (laser processability improving agent), leveling agent, antistatic agent, slip agent, antiblocking agent, antifogging agent, lubricant, dye, natural oil, synthetic oil, wax, emulsifier, magnetic material, dielectric property adjuster, and toughening agent.

The method of production of the first curable resin composition used in the present invention is not particularly limited. The above components may be mixed as they are or may be mixed in a state dissolved or dispersed in an organic solvent or part of the components may be dissolved or dispersed in an organic solvent to prepare a composition and the remaining components may be mixed into the composition.

(Second Curable Resin Composition)

Next, the second curable resin composition for foiling the second resin layer of the multilayer curable resin film of the present invention will be explained.

The second curable resin composition is a resin composition containing an alicyclic olefin polymer (B1) and a curing agent (B2).

In the present invention, by forming, in addition to the above-mentioned first resin layer comprised of the first curable resin composition, the second resin layer comprised of the second curable resin composition containing the alicyclic olefin polymer (B1) and curing agent (B2) and using the second resin layer as a plateable layer for electroless plating, it is possible to realize excellent plating adhesion. In particular, in the present invention, by using the second curable resin composition having the above configuration to form the plateable layer (second resin layer), it is possible to maintain well the above-mentioned effects obtained by the first resin layer comprised of the first curable resin composition, that is, the effect of making the obtained electrical insulating layer excellent in electrical characteristics and mechanical characteristics, while making the adhesion of the plated conductors when forming plated conductors by electroless plating excellent. Further, it is possible to realize adhesion to such plated conductors while keeping the surface roughness at the surface low.

[Alicyclic Olefin Polymer (B1)]

The alicyclic olefin polymer (B1) is not particularly limited, but one having, as an alicyclic structure, a cycloalkane structure or cycloalkene structure, etc. may be mentioned. Due to the excellent mechanical strength, heat resistance, etc., one having a cycloalkane structure is preferable. Further, the alicyclic olefin polymer preferably has a polar group. As the polar group contained in the alicyclic olefin polymer, an alcoholic hydroxyl group, phenolic hydroxyl group, carboxyl group, alkoxyl group, epoxy group, glycidyl group, oxycarbonyl group, carbonyl group, amino group, carboxylic anhydride group, sulfonic acid group, phosphoric acid group, etc. may be mentioned. Among these as well, a carboxyl group, carboxylic anhydride group, and phenolic hydroxyl group are preferable, while a carboxylic anhydride group is more preferable.

The alicyclic olefin polymer (B1) can, for example, be obtained by the following methods. That is, it can be obtained by (1) the method of polymerizing an alicyclic olefin having a polar group while adding another monomer according to need, (2) the method of copolymerizing an alicyclic olefin not having a polar group with a monomer having a polar group, (3) the method of polymerizing an aromatic olefin having a polar group while adding another monomer according to need and hydrogenating the aromatic ring part of the thus obtained polymer, (4) the method of copolymerizing an aromatic olefin not having a polar group with a monomer having a polar group and hydrogenating the aromatic ring part of the thus obtained polymer, or (5) the method of introducing a compound having a polar group in an alicyclic olefin polymer not having a polar group by a modification reaction or (6) the method of hydrolyzing the polar group of the alicyclic olefin polymer having a polar group (for example carboxyl acid ester group etc.) obtained by the above-mentioned (1) to (5) to thereby convert it to another polar group (for example carboxyl group) etc. Among these as well, a polymer obtained by the above-mentioned method of (1) is preferable.

As the polymerization method for obtaining the alicyclic olefin polymer (B1), ring opening polymerization or addition polymerization may be used. In the case of ring opening polymerization, the obtained ring-opened polymer is preferably hydrogenated.

As specific examples of the alicyclic olefin having a polar group, an alicyclic olefin having a carboxyl group such as 5-hydroxycarbonyl-bicyclo[2.2.1]hept-2-ene, 5-methyl-5-hydroxycarbonyl-bicyclo[2.2.1]hept-2-ene, 5-carboxymethyl-5-hydroxycarbonylbicyclo [2.2.1]hept-2-ene, 9-hydroxycarbonyltetracyclo[6.2.1.1^{3,6}.0^{2,7}]dodec-4-ene, 9-methyl-9-hydroxycarbonyltetracyclo[6.2.1.1^{3,6}.0^{2,7}]dodec-4-ene, 9-carboxymethyl-9-hydroxycarbonyltetracyclo[6.2.1.1^{3,6}.0^{2,7}]dodec-4-ene, 5-exo-6-endo-dihydroxycarbonylbicyclo[2.2.1]hept-2-ene, and 9-exo-10-endo-dihydroxycarbonyitetracyclo[6.2.1.1^{3,6}.0^{2,7}]dodec-4-ene; an alicyclic olefin having a carboxylic anhydride group such as bicyclo[2.2.1]hept-2-ene-5,6-dicarboxylic anhydride, tetracyclo[6.2.1.1^{3,6}.0^{2,7}]dodec-4-ene-9,10-dicarboxylic anhydride, and hexacyclo[10.2.1.1^{3,10}.1^{5,8}.0^{2,11}.0^{4,9}]heptadeca-6-ene-13,14-dicarboxylic anhydride; an alicyclic olefin having a carboxylic acid ester group such as 9-methyl-9-methoxycarbonyl-etracyclo[6.2.1.1^{3,6}.0^{2,7}]dodec-4-ene, 5-methoxycarbonyl-bicyclo[2.2.1]hept-2-ene, and 5-methyl-5-methoxycarbonyl-bicyclo[2.2.1]hept-2-ene; an alicyclic olefin having a phenolic hydroxyl group such as (5-(4-hydroxyphenyl)bicyclo[2.2.1]hept-2-ene, 9-(4-hydroxyphenyl)tetracyclo[6.2.1.1^{3,6}.0^{2,7}]dodec-4-ene, and N-(4-hydroxyphenyl)bicyclo[2.2.1]hept-5-ene-2,3-dicarboxyimide; etc. may be mentioned. These may be used as single types alone or may be used as two types or more jointly.

As specific examples of the alicyclic olefin not having a polar group, bicyclo[2.2.1]hept-2-ene (common name: norbornene), 5-ethyl-bicyclo[2.2.1]hept-2-ene, 5-butyl-bicyclo[2.2.1]hept-2-ene, 5-ethylidene-bicyclo[2.2.1]hept-2-ene, 5-methylidene-bicyclo[2.2.1]hept-2-ene, 5-vinyl-bicyclo[2.2.1]hept-2-ene, tricyclo[5.2.1.0^{2,6}]deca-3,8-diene (common name: dicyclopentadiene), tetracyclo[6.2.1.1^{3,6}.0^{2,7}]dodec-4-ene (common name: tetracyclododecene), 9-methyl-tetracyclo[6.2.1.1^{3,6}.0^{2,7}]dodec-4-ene, 9-ethyl-tetracyclo[6.2.1.1^{3,6}.0^{2,7}]dodec-4-ene, 9-methylidene-tetracyclo [6.2.1.1^{3,6}.0^{2,7}]dodec-4-ene, 9-ethylidene-tetracyclo[6.2.1.1^{3,6}.0^{2,7}]dodec-4-ene, 9-methoxycarbonyltetracyclo [6.2.1.1^{3,6}.0^{2,7}]dodec-4-ene, 9-vinyl-tetracyclo[6.2.1.1^{3,6}.0^{2,7}]dodec-4-ene, 9-propenyl-tetracyclo[6.2.1.1^{3,6}.0^{2,7}]dodec-4-ene, 9-phenyl-tetracyclo [6.2.1.1^{3,6}.0^{2,7}]dodec-4-ene, tetracyclo[9.2.1.0^{2,10}.0^{3,8}]tetradeca-3,5,7,12-tetraene, cyclopentene, cyclopentadiene, etc. may be mentioned. These may be used as single types alone or may be used as two types or more jointly.

As examples of an aromatic olefin not having a polar group, styrene, α-methylstyrene, divinylbenzene, etc. may be mentioned. When these specific examples have the above polar groups, they may be mentioned as examples of aromatic olefins having a polar group. These may be used as single types alone or may be used as two types or more jointly.

As the monomer having a polar group, other than an alicyclic olefin having a polar group, able to be copolymerized with an alicyclic olefin or aromatic olefin, an ethylenically unsaturated compound having a polar group may be mentioned. As specific examples, an unsaturated carboxylic acid compound such as acrylic acid, methacrylic acid, α-ethyl acrylic acid, 2-hydroxyethyl (meth)acrylic acid, maleic acid, fumaric acid, and itaconic acid; an unsaturated carboxylic anhydride such as maleic anhydride, butenyl succinic anhydride, tetrahydrophthalic anhydride, and citraconic anhydride; etc. may be mentioned. These may be used as single types alone or may be used as two types or more jointly.

As the monomer not having a polar group, other than an alicyclic olefin, able to be copolymerized with an alicyclic olefin or aromatic olefin, an ethylenically unsaturated compound not having a polar group may be mentioned. As specific examples, ethylene or α-olefin having 2 to 20 carbon atoms such as ethylene, propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, and 1-eicocene; nonconjugated dienes such as 1,4-hexadiene, 4-methyl-1,4-hexadiene, 5-methyl-1,4-hexadiene, and 1,7-octadiene; etc. may be mentioned. These may be used as single types alone or may be used as two types or more jointly.

The molecular weight of the alicyclic olefin polymer (B1) is not particularly limited, but, as weight average molecular weight converted to polystyrene measured by gel permeation chromatography using tetrahydrofuran as a solvent, is preferably 500 to 1,000,000 in range, more preferably 1,000 to 500,000 in range, particularly preferably 5,000 to 300,000 in range.

As the polymerization catalyst when obtaining the alicyclic olefin polymer (B1) by the ring opening polymerization method, a conventionally known metathesis polymerization catalyst can be used. As the metathesis polymerization catalyst, a transition metal compound containing an atom such as Mo, W, Nb, Ta, and Ru may be illustrated. Among them, a compound containing Mo, W, or Ru is preferable since it has a high polymerization activity. As specific examples of particularly preferable metathesis polymerization catalysts, (1) a catalyst having a molybdenum or tungsten compound having a halogen group, imide group, alkoxy group, allyloxy group, or carbonyl group as a ligand as a main catalyst and having an organometallic compound as a second ingredient or (2) a metal carbene complex catalyst having Ru as a center metal may be mentioned.

The ratio of use of the metathesis polymerization catalyst is usually 1:100 to 1:2,000,000 in range in molar ratio of (transition metal in metathesis polymerization catalyst:monomer) with respect to the monomer used for the polymerization, preferably 1:200 to 1:1,000,000 in range. If the amount of the catalyst is too large, removal of the catalyst becomes difficult, while if too small, a sufficient polymerization activity is liable to be unable to be obtained.

The polymerization reaction is usually performed in an organic solvent. The organic solvent used is not particularly limited so long as one in which the polymer dissolves or disperses under predetermined conditions and does not have an effect on the polymerization, but one generally used industrially is preferable. As specific examples of the organic solvent, an aliphatic hydrocarbon such as pentane, hexane, and heptane; an alicyclic hydrocarbon such as cyclopentane, cyclohexane, methylcyclohexane, dimethylcyclohexane, trimethylcyclohexane, ethylcyclohexane, diethylcyclohexane, decahydronaphthalene, bicycloheptane, tricyclodecane, hexahydroindenenecyclohexane, and cyclooctane; an aromatic hydrocarbon such as benzene, toluene, and xylene; a halogen-based aliphatic hydrocarbon such as dichloromethane, chloroform, and 1,2-dichloroethane; a halogen-based aromatic hydrocarbon such as chlorobenzene and dichlorobenzene; a nitrogen-containing hydrocarbon-based solvent such as nitromethane, nitrobenzene, and acetonitrile; an ether-based solvent such as diethyl ether and tetrahydrofuran; and an aromatic ether-based solvent such as anisole and phenetol; may be mentioned. Among these as well, a solvent which is in general use industrially such as an aromatic hydrocarbon-based solvent or aliphatic hydrocarbon-based solvent, alicyclic hydrocarbon-based solvent, ether-based solvent, or aromatic ether-based solvent is preferable.

The amount of the organic solvent used is preferably an amount giving a concentration of the monomer in the polymerization solution of 1 to 50 wt %, preferably an amount giving 2 to 45 wt %, particularly preferably an amount giving 3 to 40 wt %. If the concentration of the monomer is less than 1 wt %, the productivity becomes poorer, while if it exceeds 50 wt %, the solution viscosity after polymerization becomes too high and the subsequent hydrogenation reaction sometimes becomes difficult.

The polymerization reaction is started by mixing the monomer used for the polymerization and the metathesis polymerization catalyst. As methods for mixing these, it is possible to add the metathesis polymerization catalyst solution to the monomer solution or vice versa. When the metathesis polymerization catalyst used is a mixed catalyst of a main catalyst comprised of a transition metal compound and a second ingredient comprised of an organometallic compound, a reaction solution of the mixed catalyst may also be added to the monomer solution or vice versa. Further, a transition metal compound solution may be added to a mixed solution of the monomer and organometallic compound or vice versa. Furthermore, an organometallic compound may be added to a mixed solution of the monomer and transition metal compound or vice versa.

The polymerization temperature is not particularly limited, but is usually −30° C. to 200° C., preferably 0° C. to 180° C. The polymerization time is not particularly limited, but is usually 1 minute to 100 hours.

As the method of adjusting the molecular weight of the obtained alicyclic olefin polymer (B1), the method of adding a suitable amount of a vinyl compound or diene compound may be mentioned. The amount of the vinyl compound or diene compound added may be freely selected in accordance with the targeted molecular weight between 0.1 to 10 mol % with respect to the monomer used for the polymerization.

As the polymerization catalyst in the case of obtaining the alicyclic olefin polymer (B1) by the addition polymerization method, for example, a catalyst comprised of a titanium, zirconium, or vanadium compound and an organoaluminum compound may be suitably used. These polymerization catalysts may be used respectively independently or as two types or more combined. The amount of the polymerization catalyst is usually 1:100 to 1:2,000,000 in range by molar ratio of the metal compound in the polymerization catalyst:monomer used for the polymerization.

When using a hydrogenate of a ring-opened polymer as an alicyclic olefin polymer (B1), the hydrogenation of the ring-opened polymer is usually performed using a hydrogenation catalyst. The hydrogenation catalyst is not particularly limited. One in general use at the time of hydrogenation of an olefin compound may be suitably employed. As specific examples of the hydrogenation catalyst, for example, a Ziegler-based catalyst which is comprised of a combination of a transition metal compound and alkali metal compound such as cobalt acetate and triethylaluminum, nickel acetylacetonate and triisobutylaluminum, titanocene dichloride and n-butyllithium, zirconocene dichloride and sec-butyllithium, and tetrabutoxytitanate and dimethylmagnesium; precious metal complex catalysts such as dichlorotris(trihenylphosphine)rhodium and ruthenium compounds which are described in Japanese Patent Publication No. 7-2929A, Japanese Patent Publication No. 7-149823A, Japanese Patent Publication No. 11-209460A, Japanese Patent Publication No. 11-158256A, Japanese Patent Publication No. 11-193323A, Japanese Patent Publication No. 11-209460A, etc., for example, bis(tricyclohexylphosphine)benzylidine ruthenium (IV) dichloride; and other homogeneous catalysts may be mentioned. Further, a nonhomogeneous catalyst comprised of a metal such as nickel, palladium, platinum, rhodium, and ruthenium carried on a carrier such as carbon, silica, diatomaceous earth, alumina, and titanium oxide, for example, nickel/silica, nickel/diatomaceous earth, nickel/alumina, palladium/carbon, palladium/silica, palladium/diatomaceous earth, palladium/alumina, etc. may also be used. Further, the above-mentioned metathesis polymerization catalyst may also be used as is as a hydrogenation catalyst.

The hydrogenation reaction is usually performed in an organic solvent. The organic solvent can be suitably selected by the solubility of the produced hydrogenate. It is possible to use an organic solvent similar to the organic solvent used for the above-mentioned polymerization reaction. Therefore, after the polymerization reaction, it is possible to add a hydrogenation catalyst to cause a reaction without changing the organic solvent. Furthermore, in the organic solvents which are used for the above-mentioned polymerization reaction, from the viewpoint of not reacting at the time of the hydrogenation reaction, an aromatic hydrocarbon-based solvent, aliphatic hydrocarbon-based solvent, alicyclic hydrocarbon-based solvent, ether-based solvent, or aromatic ether-based solvent is preferable, and an aromatic ether-based solvent is more preferable.

The hydrogenation reaction conditions may be suitably selected in accordance with the type of the hydrogenation catalyst used. The reaction temperature is usually −20 to 250° C., preferably −10 to 220° C., more preferably 0 to 200° C. If less than −20° C., the reaction speed becomes slow, while conversely if over 250° C., secondary reactions easily occur. The pressure of the hydrogen is usually 0.01 to 10.0 MPa, preferably 0.05 to 8.0 MPa. If the hydrogen pressure is less than 0.01 MPa, the hydrogenation speed becomes slow, while if over 10.0 MPa, a high pressure resistant reaction system becomes necessary.

The time of the hydrogenation reaction is suitably selected so as to control the hydrogenation rate. The reaction time is usually 0.1 to 50 hours in range. It is possible to hydrogenate 50% or more of the carbon-carbon double bonds of the main chain of the polymer, preferably 70% or more, more preferably 80% or more, particularly preferably 90% or more.

After the hydrogenation reaction is performed, it is also possible to perform treatment for removing the catalyst used for the hydrogenation reaction. The method of removal of the catalyst is not particularly limited, but a method such as centrifugation or filtration may be mentioned. Furthermore, it is also possible to add a catalyst deactivating agent such as water or alcohol or add an adsorbent such as activated clay, alumina, and diatomaceous earth to promote the removal of the catalyst.

[Curing Agent (B2)]

The curing agent (B2) contained in the second curable resin composition used in the present invention is not particularly limited so long as one enabling the formation of a cross-linked structure in the alicyclic olefin polymer (B1) by heating. A curing agent mixed into a resin composition for forming a general electrical insulating film can be used. As the curing agent (B2), it is preferable to use a polyvalent reactive group-containing compound having two or more functional groups which can react with the alicyclic olefin polymer (B1) used to form bonds.

For example, as the curing agent (B2) which is suitably used when using an alicyclic olefin polymer (B1) comprised of an alicyclic olefin polymer having a carboxyl group, carboxylic anhydride group or phenolic hydroxyl group, a polyvalent epoxy compound, polyvalent isocyanate compound, polyvalent amine compound, polyvalent hydrazide compound, aziridine compound, basic metal oxide, organometallic halide, etc. may be mentioned. These may be used as single types alone or may be used as two types or more jointly. Further, by using these compounds together with peroxides, use as a curing agent is also possible.

Among these as well, as the curing agent (B2), a polyvalent epoxy compound is preferable since it has moderate reactivity with the alicyclic olefin polymer (B1) and handling of the second curable resin composition becomes easy. A glycidyl ether type epoxy compound or alicyclic polyvalent epoxy compound is particularly preferably used. As commercially available products of a glycidyl ether type epoxy compound, for example, a polyvalent epoxy compound such as product name “Epiclon HP7200L, Epiclon HP7200, Epiclon HP7200H, Epiclon HP7200HH, Epiclon HP7200HHH” (above made by DIC, “Epiclon” is a registered trademark); product name “Denacol EX512” and “Denacol EX721” (above made by Nagase Chemtex, “Denacol” is a registered trademark) may be mentioned. As the alicyclic polyvalent epoxy compound, for example, a polyvalent epoxy compound such as product name “Epolead GT401 and Celloxide 2021P” (above made by Daicel Chemical, “Epolead” and “Celloxide” are registered trademarks) may be mentioned.

In the second curable resin composition, the amount of the curing agent (B2) is not particularly limited, but it is preferably 1 to 100 parts by weight with respect to 100 parts by weight of the alicyclic olefin polymer (B1), more preferably 5 to 80 parts by weight, still more preferably 10 to 50 parts by weight in range. By making the amount of the curing agent (B2) the above range, it is possible to make the obtained electrical insulating layer better in mechanical strength and electrical characteristics.

[Inorganic Filler (83)]

The second curable resin composition used in the present invention preferably further contains an inorganic filler (B3). The inorganic filler (B3) is not particularly limited, but, for example, calcium carbonate, magnesium carbonate, barium carbonate, zinc oxide, titanium oxide, magnesium oxide, magnesium silicate, calcium silicate, zirconium silicate, hydrated alumina, magnesium hydroxide, aluminum hydroxide, barium sulfate, silica, talc, clay, etc. may be mentioned. Among these as well, from the viewpoint of the excellent electrical characteristics and heat resistance, silica is preferable. Note that the inorganic filler (B3) may also be treated on its surface in advance by a silane coupling agent etc. In the present invention, by including, as the second curable resin composition, an inorganic filler (B3) in addition to the above-mentioned alicyclic olefin polymer (B1) and curing agent (B2), it is possible to make the second resin layer one with a low surface roughness at its surface while making the adhesion of the plated conductors when forming plated conductors by electroless plating better.

The average particle size of the inorganic filler (83) is not particularly limited, but is preferably 0.05 to 5 μm, more preferably 0.1 to 2 μm, particularly preferably 0.2 to 1 μm. Further, in the second curable resin composition used in the present invention, the content of the inorganic filler (B3) is not particularly limited, but is preferably 5 to 70 wt % by conversion to solid content, more preferably 10 to 60 wt %, particularly preferably 15 to 50 wt %. By making the content of the inorganic filler (B3) this range, it is possible to make the adhesion of the plated conductors famed better.

[Other Ingredients]

The second curable resin composition used in the present invention may further suitably contain, in addition to the above ingredients, other ingredients such as described below to an extent not impairing the realization of the effects of the present invention.

That is, the second curable resin composition used in the present invention may contain a hindered phenol compound or hindered amine compound.

A hindered phenol compound is a phenol compound having a hydroxyl group and having in its molecule at least one hindered structure not having a hydrogen atom at the carbon atom of the β-position of the hydroxyl group. As specific examples of the hindered phenol compound, 1,1,3-tris-(2-methyl-4-hydroxy-5-tert-butylphenyl)butane, 4,4′-butylidenebis-(3-methyl-6-tert-butylphenol), 2,2-thiobis(4-methyl-6-tert-butylphenol), n-octadecyl-3-(4′-hydroxy-3′,5′-di-tert-butyl-phenyl)propionate, tetrakis-[methylene-3-(3′,5′-di-tert-butyl-4′-hydroxyphenyl)propionate]methane, etc. may be mentioned.

In the second curable resin composition, the amount of the hindered phenol compound is not particularly limited, but is preferably 0.04 to 10 parts by weight with respect to 100 parts by weight of the alicyclic olefin polymer (B1), more preferably 0.3 to 5 parts by weight, still more preferably 0.5 to 3 parts by weight in range.

Further, a hindered amine compound is a compound having in its molecule at least one 2,2,6,6-tetraalkylpiperidine group having a secondary amine or tertiary amine at the 4-position. The number of carbon atoms of the alkyl is usually 1 to 50. As the hindered amine compound, a compound having in its molecule at least one 2,2,6,6-tetramethylpiperidyl group having a secondary amine or tertiary amine at the 4-position is preferable. Note that, in the present invention, the hindered phenol compound and hindered amine compound are preferably jointly used. By jointly using these, when roughening the surface of the cured product obtained by curing the multilayer curable resin film of the present invention using an aqueous solution of a permanganate etc., even if the surface roughening treatment conditions change, it is possible to reduce the surface roughness of the cured product after the surface roughening treatment.

As specific examples of the hindered amine compound, bis(2,2,6,6-tetramethyl-4-piperidyl)sebacate, bis(1,2,2,6,6-pentamethyl-4-piperidyl)sebacate, 1[2-{3-(3,5-di-tert-butyl-4-hydroxyphenyl) propionyloxy}ethyl]-4-{3-(3,5-di-tert-butyl-4-hydroxyphenyl) propionyloxy}-2,2,6,6-tetramethylpiperidine, 8-benzyl-7,7,9,9-tetramethyl-3-octyl-1,2,3-triazaspiro[4,5]undecane-2,4-dione etc. may be mentioned.

In the second curable resin composition, the amount of the hindered amine compound is not particularly limited, but is usually 0.02 to 10 parts by weight with respect to 100 parts by weight of the alicyclic olefin polymer (B1), preferably 0.2 to 5 parts by weight, more preferably 0.25 to 3 parts by weight.

Further, the second curable resin composition used in the present invention may contain a curing accelerator, in addition to the above ingredients. As the curing accelerator, a curing accelerator mixed into general resin compositions for forming electrical insulating coatings may be used. For example, an aliphatic polyamine, aromatic polyamine, secondary amine, tertiary amine, acid anhydride, imidazole derivative, organic acid hydrazide, dicyandiamide, and their derivatives, urea derivatives, etc. may be mentioned. Among these as well, an imidazole derivative is particularly preferable.

The imidazole derivative is not particularly limited so long as a compound having an imidazole structure, but, for example, an alkyl-substituted imidazole compound such as 2-ethylimidazole, 2-ethyl-4-methylimidazole, bis-2-ethyl-4-methylimidazole, 1-methyl-2-ethylimidazole, 2-isopropylimidazole, 2,4-dimethylimidazole, and 2-heptadecylimidazole; an imidazole compound substituted by hydrocarbon group containing a ring structure such as an aryl group or aralkyl group such as 2-phenylimidazole, 2-phenyl-4-methylimidazole, 1-benzyl-2-methylimidazole, 1-benzyl-2-ethylimidazole, 1-benzyl-2-phenylimidazole, benzimidazole, and 2-ethyl-4-methyl-1-(2′-cyanoethyl)imidazole, etc. may be mentioned. These may be used as single types alone or as two types or more combined.

In the second curable resin composition, the amount of the curing accelerator may be suitably selected in accordance with the objective of use, but is preferably 0.001 to 10 parts by weight with respect to 100 parts by weight of the alicyclic olefin polymer (B1), more preferably 0.01 to 5 parts by weight, still more preferably 0.03 to 3 parts by weight.

Further, the second curable resin composition used in the present invention may suitably contain, in addition to the above ingredients, in the same way as the above first curable resin composition, known ingredients such as a curing accelerator, flame retardant, flame retardant aid, heat resistance stabilizer, weather resistance stabilizer, antiaging agent, UV absorbent (laser processability improving agent), leveling agent, antistatic agent, slip agent, antiblocking agent, antifogging agent, lubricant, dye, natural oil, synthetic oil, wax, emulsifier, magnetic material, dielectric property adjuster, and toughening agent. The ratios of content of these optional ingredients may be suitably selected in ranges not impairing the object of the present invention.

The method of production of the second curable resin composition used in the present invention is not particularly limited, but the above ingredients may be mixed as they are or may be mixed in a state dissolved or dispersed in an organic solvent. It is also possible to prepare a composition in a state where parts of the ingredients are dissolved or dispersed in an organic solvent and mix the remaining ingredients in that composition.

(Multilayer Curable Resin Film and Method of Production of Multilayer Curable Resin Film)

The multilayer curable resin film of the present invention is a curable multilayer film comprised of a first resin layer comprised of the above-mentioned first curable resin composition and a second resin layer comprised of the comprised of the above-mentioned second curable resin composition and is produced using the above-mentioned first curable resin composition and second curable resin composition. Specifically, the multilayer curable resin film of the present invention may, for example, be produced by the following two methods: (1) the method of coating, spraying, or flow casting the above-mentioned second curable resin composition on a support and drying it if desired to form a second resin layer, then, further coating or flow casting the above-mentioned first curable resin composition on it and drying it if desired to form the first resin layer and (2) the method of coating, spraying, or flow casting the above-mentioned second curable resin composition on a support and drying it if desired to obtain a shape or film shape of a second resin layer shaped article, coating, spraying, or flow casting the above-mentioned first curable resin composition on a support and drying it if desired to obtain a sheet shape or film shape of a first resin layer shaped article, and laminating and joining these shaped articles. Among these methods of production, the method of production of the above (1) is preferable since the process is simple and the productivity is better.

In the above-mentioned method of production of (1), when coating, spraying, or flow casting the second curable resin composition on the support and when coating, spraying, or flow casting the first curable resin composition on the second resin layer obtained by oating, spraying, or flow casting the second curable resin composition or, in the above-mentioned method of production of (2), when forming the second curable resin composition and first curable resin composition into sheet shapes or film shapes to form the second resin layer shaped article and first resin layer shaped article, the second curable resin composition or first curable resin composition is preferably coated, sprayed, or flow cast on the support while adding an organic solvent as desired.

As the support used at this time, a film shaped support such as a resin film or metal foil (support film) may be mentioned. As the resin film, a polyethylene terephthalate film, polypropylene film, polyethylene film, polycarbonate film, polyethylene naphthalate film, polyarylate film, nylon film, etc. may be mentioned. Among these films, from the viewpoint of the heat resistance, chemical resistance, peelability, etc., a polyethylene terephthalate film or polyethylene naphthalate film is preferable. As the metal foil, a copper foil, aluminum foil, nickel foil, chromium foil, gold foil, silver foil, etc. may be mentioned. Note that, the surface average roughness Ra of the support film is usually 300 nm or less, preferably 150 nm or less, more preferably 100 nm or less.

In the method of production of the above-mentioned (1), the thicknesses of the second resin layer comprised of the second curable resin composition and first resin layer comprised of the first curable resin composition or, in the method of production of the above-mentioned (2), the thicknesses of the second resin layer shaped article and first resin layer shaped article are not particularly limited, but when made into a multilayer film, they are preferably made thicknesses so that the thickness of the second resin layer becomes preferably 1 to 10 μm, more preferably 1.5 to 8 μm, still more preferably 2 to 5 μm and, further, the thickness of the first resin layer becomes preferably 5 to 100 μm, more preferably 10 to 80 μm, still more preferably 15 to 60 μm. If the second resin layer is too thin, when using electroless plating to form a conductor layer on the cured product obtained by curing the multilayer curable resin film, the shapeability of the conductor layer is liable to end up falling, while if the second resin layer is too thick, the cured product obtained by curing the multilayer curable resin film is liable to end up falling in electrical characteristics and mechanical characteristics. Further, if the first resin layer is too thin, the multilayer curable resin film is liable to end up falling in interconnect embedding ability.

As the method of coating the second curable resin composition and first curable resin composition, a method such as a dip coat, roll coat, curtain coat, die coat, slit coat, or gravure coat may be mentioned.

Further, in the method of production of the above-mentioned (1), after coating, spraying, or flow casting the second curable resin composition on the support or after coating, spraying, or flow casting the first curable resin composition on the second resin layer comprised of the second curable resin composition or, in the method of production of the above-mentioned (2), after coating the second curable resin composition and first curable resin composition on the support, drying may be performed as desired. The drying temperature is preferably made a temperature of an extent where the second curable resin composition and first curable resin composition will not cure, normally is 20 to 300° C., preferably is 30 to 200° C. Further, the drying time is usually 30 seconds to 1 hour, preferably 1 minute to 30 minutes.

In the multilayer curable resin film of the present invention, the second resin layer and first resin layer forming the multilayer curable resin film are uncured or semicured in state. Due to this, the multilayer curable resin film of the present invention exhibits curing reactivity and can be made high in adhesion.

(Prepreg)

The prepreg of the present invention is comprised of the above-mentioned multilayer curable resin film of the present invention including a fiber substrate.

As the fiber substrate, an organic fiber such as a polyamide fiber, polyaramide fiber, and polyester fiber or an inorganic fiber such as a glass fiber and carbon fiber may be mentioned. Further, as the form of the fiber substrate, the form of a woven fabric of a plain weave or twill weave or the form of nonwoven fabric etc. may be mentioned. The thickness of the fiber substrate is preferably 5 to 100 μm, more preferably 10 to 50 μm in range. If too thin, the handling becomes difficult, while if too thick, the resin layer becomes relatively thin and the interconnect embedding ability becomes insufficient in some cases.

The prepreg of the present invention is preferably one which has the second resin layer comprised of the second curable resin composition at one surface and the first resin layer comprised of the first curable resin composition at the other surface and which has the fiber substrate at the inside. The method of production is not limited, but, for example, it may be produced by the following methods: (1) the method of production by making the first curable resin composition with the support and the second curable resin composition with the support sandwich the fiber substrate so that the resin layer surfaces of the films face each other and, if desired, laminating them under conditions of pressure, vacuum, heating, etc.; (2) the method of production by impregnating either of the first curable resin composition or second curable resin composition in a fiber substrate and, if desired, drying it to prepare a prepreg and coating, spraying, or flow casting another resin composition on this prepreg or stacking still another supported resin composition film on it; and (3) the method of production by coating, spraying, or flow casting either of the first curable resin composition or second curable resin composition on a support to laminate it, stacking a fiber substrate on top of this, and further coating, spraying, or flow casting another resin composition from the top of that to laminate it and, if desired, drying it; etc. Note that in each method, it is preferable to add as desired an organic solvent to the first curable resin composition and second curable resin composition to adjust the viscosity of the first curable resin composition and second curable resin composition and thereby control the workability in the impregnation in the fiber substrate and coating, spraying, or flow casting on the support.

Further, as the support which is used at this time, a resin film such as a polyethylene terephthalate film, polypropylene film, polyethylene film, polycarbonate film, polyethylene naphthalate film, polyacrylate film, and nylon film or a metal foil such as copper foil, aluminum foil, nickel foil, chromium foil, gold foil, and silver foil may be mentioned. These may be attached to just one side of the prepreg or both sides.

Note that, the first curable resin composition and second curable resin composition may be impregnated in a fiber substrate, then dried as desired. The drying temperature is preferably made a temperature of an extent whereby the first curable resin composition and second curable resin composition will not cure, usually 20 to 300° C., preferably 30 to 200° C. If the drying temperature is too high, the curing reaction will proceed too far and the obtained prepreg is liable to no longer be uncured or semicured in state. Further, the drying time is usually 30 seconds to 1 hour, preferably 1 minute to 30 minutes.

The thickness of the prepreg of the present invention is not particularly limited, but the thickness of the second resin layer is preferably 1 to 10 μm, more preferably 1.5 to 8 μm, still more preferably 2 to 5 μm. Further, it is preferably made a thickness such that the thickness of the first resin layer becomes preferably 10 to 100 μm, more preferably 10 to 80 μm, still more preferably 15 to 60 μm.

When producing the prepreg of the present invention, as the method of coating the first curable resin composition and second curable resin composition, a method such as a dip coat, roll coat, curtain coat, die coat, slit coat, and gravure coat may be mentioned.

Also, in the prepreg of the present invention, in the same way as the above-mentioned multilayer curable resin film of the present invention, the resin composition forming the prepreg is preferably uncured or semicured in state.

Further, the thus obtained prepreg of the present invention can be made a cured product by heating and curing it. The curing is preferably performed in an inert gas atmosphere (for example, in a nitrogen atmosphere). Further, the curing may be performed in the state with the support attached or may be performed after peeling off the support.

The curing temperature is usually 30 to 400° C., preferably 70 to 300° C., more preferably 100 to 200° C. Further, the curing time is 0.1 to 5 hours, preferably 0.5 to 3 hours. The heating method is not particularly limited, but, for example, an electric oven etc. may be used.

(Laminate)

The laminate of the present invention is obtained by laminating the above-mentioned multilayer curable resin film or prepreg of the present invention on a substrate. The laminate of the present invention need only be any of the above-mentioned multilayer curable resin film or prepreg laminated on a substrate, but one comprised of a board which has a conductor layer on its surface and an electrical insulating layer comprised of a multilayer curable resin film or prepreg of the present invention laminated together is preferable.

The board which has a conductor layer on its surface is comprised of an electrical insulating board on the surface of which a conductor layer is provided. The electrical insulating board is formed by curing a resin composition which contains a known electrical insulating material (for example, alicyclic olefin polymer, epoxy compound, maleimide resin, (meth)acrylic resin, diallyl phthalate resin, triazine resin, polyphenylene ether, glass, etc.). The conductor layer is not particularly limited, but is usually a layer which includes interconnects which are formed from a conductor such as a conductive metal and may further contain various circuits. The configuration, thickness, etc. of the interconnects and circuits are not particularly limited. As specific examples of the board which has a conductor layer on its surface, a printed circuit board, silicon wafer board, etc. may be mentioned. The thickness of the board which has a conductor layer on its surface is usually 10 μm to 10 mm, preferably 20 μm to 5 mm, more preferably 30 μm to 2 mm.

The board which has a conductor layer on its surface used in the present invention is preferably pretreated on the surface of the conductor layer so as to improve the adhesion with the electrical insulating layer. As the method of pretreatment, known art can be used without particular limitation. For example, if the conductor layer is comprised of copper, the oxidizing method of bringing a strong alkaline oxidizing solution into contact with the conductor layer surface to form a layer of copper oxide on the conductor surface and roughen it, the method of oxidizing the conductor layer surface by the previous method, then reducing it by sodium borohydride, formalin, etc., the method of depositing plating on the conductor layer to roughen it, the method of bringing an organic acid into contact with the conductor layer to dissolve the grain boundaries of the copper and roughen the layer, the method of forming a primer layer on the conductor layer by a thiol compound, silane compound, etc. and the like may be mentioned. Among these, from the viewpoint of the ease of maintaining the shapes of fine wiring patterns, the method of bringing an organic acid into contact with the conductor layer to dissolve the grain boundaries of the copper and roughen the layer and the method of using thiol compounds or silane compounds etc. to form a primer layer are preferable.

The laminate of the present invention can usually be produced by hot pressing bonding the first resin layer forming the above-mentioned multilayer curable resin film or prepreg of the present invention formed on a board having a conductor layer at its surface so as to contact that board.

As the method of hot press bonding, the method of superposing multilayer curable resin film or prepreg with the support on the above-mentioned board so that the first resin layer forming the multilayer curable resin film or prepreg of the present invention contacts the conductor layer and using a press machine such as a press laminator, press, vacuum laminator, vacuum press, or roll laminator for hot press bonding (lamination) may be mentioned. By hot press bonding, it is possible to bond the conductor layer on the board surface and the multilayer curable resin film or prepreg so that substantially no clearance is present at the interface. The multilayer curable resin film or prepreg is usually laminated on the conductor layer of the board in an uncured or semicured state.

The temperature of the hot press bonding operation is usually 30 to 250° C., preferably 70 to 180° C., the pressure applied is usually 10 kPa to 20 MPa, preferably 100 kPa to 10 MPa, and the time is usually 30 seconds to 5 hours, preferably 1 minute to 3 hours. Further, the hot press bonding is preferably performed under reduced pressure so as to improve the embedding ability of the interconnect patterns and keep down the formation of bubbles. The pressure at the reduced pressure for hot pressing bonding is usually 100 kPa to 1 Pa, preferably 40 kPa to 10 Pa.

(Cured Product)

The cured product of the present invention is obtained by curing the multilayer curable resin film of the present invention and includes any of the prepreg and laminate of the present invention which is comprised of the cured multilayer curable resin film. The curing can be performed by suitably heating the first curable resin composition and second curable resin composition forming the multilayer curable resin film of the present invention under the later explained curing conditions.

For example, the laminate of the present invention can be made into a cured product by treatment to cure the multilayer curable resin film or prepreg of the present invention forming the same. The curing is usually performed by heating the board as a whole where the multilayer curable resin film or prepreg of the present invention is formed on the conductor layer. The curing can be performed simultaneously with the above-mentioned hot press bonding operation. Further, first, the hot press bonding operation may be performed under conditions where curing does not occur, that is, at a relatively low temperature and short time, and then curing performed. The hot press bonding and curing are preferably performed in an inert gas atmosphere (for example, in a nitrogen atmosphere). Further, the hot press bonding and curing may be performed in the state with the support attached or may be performed after peeling off the support.

Further, for the purpose of improving the flatness of the electrical insulating layer or the purpose of increasing the thickness of the electrical insulating layer, it is also possible to bond two or more multilayer curable resin films or prepregs of the present invention on a conductor layer of a board for lamination.

The curing temperature is usually 30 to 400° C., preferably 70 to 300° C., more preferably 100 to 200° C. Further, the curing time is usually 0.1 to 5 hours, preferably 0.5 to 3 hours. The method of heating is not particularly limited. For example, an electrical oven etc. may be used for this.

(Composite)

The composite of the present invention is comprised of the cured product of the present invention on the surface of which a conductor layer is formed.

For example, when the composite of the present invention forms a multilayer board, the composite of the present invention is comprised of a laminate on the electrical insulating layer of which a still other conductor layer is formed. As the conductor layer, a metal plating or metal foil can be used. As the metal plating material, gold, silver, copper, rhodium, palladium, nickel, tin, etc. may be mentioned. As the metal foil, one which is used as the support of the above-mentioned multilayer curable resin film or prepreg may be mentioned. Note that, in the present invention, the method of using metal plating as the method for forming conductor layer is preferable from the viewpoint that fine interconnects can be formed. Below, the method of production of the composite of the present invention will be explained illustrating a multilayer circuit board in which metal plating is used as the conductor layer as one example of the composite of the present invention.

First, the laminate is formed with via holes or through holes which pass through the electrical insulating layer. The via holes are formed for connecting the different conductor layers which form a multilayer circuit board when forming a multilayer circuit board. The via holes and through holes can be formed by chemical treatment such as photolithography or by physical treatment such as drilling, laser irradiation, and plasma etching. Among these methods, the method using a laser (CO₂ gas laser, excimer laser, UV-YAG laser, etc.) enables fine via holes to be formed without causing a drop in the characteristics of the electrical insulating layer, so this is preferred.

Note that, in the present invention, when obtaining the above-mentioned laminate and cured product, if using a multilayer curable resin film or prepreg with a support, it is possible to employ processing of irradiating a laser from the support side to form via holes or through holes as is in the state with the support attached, then peeling off the support or possible to peel off the support, then form the via holes or through holes. In the present invention, from the viewpoint of being able to mitigate the damage to the surface of the electrical insulating layer due to the formation of the via holes or through holes or being able to reduce the difference between the bottom diameters and top diameters of the vias, the method of irradiating the laser from the support side as is in the state with the support attached is preferable.

Next, the surface of the electrical insulating layer of the laminate (that is, the cured product of the present invention), specifically, the surface of the second resin layer side, is treated by surface roughening to roughen it. The treatment for surface roughening is performed so as to raise the adhesion with the conductor layer which is formed on the electrical insulating layer (specifically, on the second resin layer).

The surface average roughness Ra of the electrical insulating layer is preferably 0.05 μm or more and less than 0.5 μm, more preferably 0.06 μm or more and 0.3 μm or less, still more preferably 0.07 μm or more and 0.2 μm or less, while the surface 10-point average roughness Rzjis is preferably 0.3 μm or more and less than 5 μm, more preferably 0.5 μm or more and 3 μm or less. Note that, in the present description, Ra is the arithmetic average roughness shown in JIS B0601-2001, while the surface 10-point average roughness Rzjis is the 10-point average roughness shown in JIS B0601-2001 Annex 1. In particular, in the present invention, as the second curable resin composition for forming the second resin layer forming the plateable layer, one having the above constitution is used, so even when making the surface roughness a relatively low one such as explained above, it is possible to make the adhesion with the conductor layer comprised of the metal plating coating a good one.

Further, the method of surface roughening treatment is not particularly limited, but the method of bringing the surface of the electrical insulating layer into contact with an oxidizing compound etc. may be mentioned. As the oxidizing compound, an inorganic oxidizing compound or organic oxidizing compound or other known compound which has an oxidizing ability may be mentioned. From the ease of control of the surface average roughness of the electrical insulating layer, use of an inorganic oxidizing compound or organic oxidizing compound is particularly preferable. As the inorganic oxidizing compound, a permanganate, chromic acid anhydride, dichromate, chromate, persulfate, active manganese dioxide, osmium tetraoxide, hydrogen peroxide, periodide, etc. may be mentioned. As the organic oxidizing compound, dicumyl peroxide, octanoyl peroxide, m-chloroperbenzoate, peracetate, ozone, etc. may be mentioned.

The method of using an inorganic oxidizing compound or organic oxidizing compound to roughen the surface of the electrical insulating layer is not particularly limited. For example, the method of dissolving the above oxidizing compound in a solvent which can dissolve it so as to prepare an oxidizing compound solution and bringing this into contact with the surface of the electrical insulating layer may be mentioned. The method of bringing the oxidizing compound solution into contact with the surface of the electrical insulating layer is not particularly limited, but, for example, the dipping method of dipping the electrical insulating layer in the oxidizing compound solution, the buildup method of utilizing the surface tension of the oxidizing compound solution to place the oxidizing compound solution on the electrical insulating layer, the spraying method of spraying the oxidizing compound solution on the electrical insulating layer, or any other method may also be used.

The temperature and the time by which these oxidizing compound solutions are brought into contact with the surface of the electrical insulating layer may be freely set by considering the concentration and type of the oxidizing compound, method of contact, etc., but the temperature is usually 10 to 150° C., preferably 20 to 100° C., while the time is usually 0.5 to 60 minutes, preferably 1 to 40 minutes.

Note that, to remove the oxidizing compound after the surface roughening treatment, the surface of the electrical insulating layer after the surface roughening treatment is washed with water. Further, when a substance which cannot be washed off by just water is deposited on the surface, the surface is further washed by a washing solution which can dissolve that substance or another compound is brought into contact with the surface to convert the substance into one which can be dissolved in water and then the surface is washed by water. For example, when bringing an aqueous solution of potassium permanganate or an aqueous solution of sodium permanganate or other alkali aqueous solution into contact with the electrical insulating layer, to remove the film of manganese dioxide which is formed, it is possible to using a mixed solution of hydroxylamine sulfate and sulfuric acid or other acidic aqueous solution to neutralize/reduce the surface, then wash it by water.

Next, after the electrical insulating layer of the laminate is treated to roughen its surface, a conductor layer is formed on the surface of the electrical insulating layer and the inside wall surfaces of the via holes or through holes.

The method of formation of the conductor layer is preferably the electroless plating method from the viewpoint of enabling the formation of a conductor layer excellent in adhesion.

For example, when using electroless plating to form a conductor layer, first, before forming a metal thin layer on the surface of the electrical insulating layer, the general practice has been to deposit silver, palladium, zinc, cobalt, or another catalyst nuclei on the electrical insulating layer. The method of depositing catalyst nuclei on the electrical insulating layer is not particularly limited, but, for example, the method of dipping the article in a solution obtained by dissolving silver, palladium, zinc, cobalt, or other metal compounds or their salts or complexes in water, alcohol, chloroform another organic solvent in 0.001 to 10 wt % in concentration (as desired, also possibly including an acid, alkali, complexing agent, reducing agent, etc.), then reducing the metal etc. may be mentioned.

As the electroless plating solution which is used in the electroless plating, a known self-catalyst type electroless plating solution may be used. It is not particularly limited in the type of metal, the type of reducing agent, the type of complexing agent, the concentration of hydrogen ions, the concentration of dissolved oxygen, etc. which are contained in the plating solution. For example, an electroless copper plating solution which contains ammonium hypophosphite, hypophosphoric acid, ammonium borohydride, hydrazine, formalin, etc. as a reducing agent; an electroless nickel-phosphorus plating solution which contains sodium hypophosphite as a reducing agent; an electroless nickel-boron plating solution which contains dimethylamineborane as a reducing agent; an electroless palladium plating solution; an electroless palladium-phosphorus plating solution which contains sodium hypophosphite as a reducing agent; an electroless gold plating solution; an electroless silver plating solution; an electroless nickel-cobalt-phosphorus plating solution which contains sodium hypophosphite as a reducing agent, or other electroless plating solution can be used.

After forming the metal thin layer, the substrate surface may be brought into contact with a rustproofing agent to make it rustproof. Further, after forming the metal thin layer, the metal thin layer may be heated to raise the adhesiveness. The heating temperature is usually 50 to 350° C., preferably 80 to 250° C. Note that, at this time, the heating may be performed under pressed conditions. As the pressing method at this time, for example, the method of using a hot press, a pressurizing and heating roll, and other physical pressing means may be mentioned. The pressure which is applied is usually 0.1 to 20 MPa, preferably 0.5 to 10 MPa. If this range, high adhesion can be secured between the metal thin layer and the electrical insulating layer.

The thus formed metal thin layer is formed with a plating-use resist pattern and the plating is further grown over it by electroplating or other wet plating (thickening plating). Next, the resist is removed and the surface is further etched to etch the metal thin layer into the pattern shapes and form the conductor layer. Therefore, the conductor layer which is formed by this method is usually comprised of the patterned metal thin layer and the plating which is grown over that.

Alternatively, when using metal foil instead of metal plating as the conductor layer forming the multilayer circuit board, the following method can be used for production.

That is, first, the same procedure is followed as above to prepare a laminate comprised of an electrical insulating layer comprised of a multilayer curable resin or prepreg and a conductor layer comprised of a metal foil. As such a laminate, when forming the laminate, it is preferable to make the compositions forming the multilayer curable resin film a hardness enabling the required properties to be held and to prevent problems when subsequently working it or when forming a multilayer circuit board. In particular, it is preferable to form the laminate under a vacuum. Note that, a laminate which is comprised of such an electrical insulating layer comprising a multilayer curable resin film or prepreg and a conductor layer comprising a metal foil can, for example, be used for a printed circuit board by a known subtractive method.

Further, the prepared laminate is formed with, in the same way as above, via holes or through holes which pass through the electrical insulating layer, then the resin residue in the famed via holes is removed by desmearing the laminate which forms the through holes. The method of desmearing is not particularly limited, but for example the method of causing contact with a solution of an oxidizing compound such as a permanganate (desmearing solution) may be mentioned. Specifically, the laminate which is formed with the via holes can be dipped in a 60 to 90° C. aqueous solution prepared to contain 70 g/liter of sodium permanganate and 40 g/liter of sodium hydroxide for 1 to 50 minutes with shaking so as to desmear it.

Next, after the laminate is desmeared, a conductor layer is formed at the inside wall surfaces of the via holes. The method of forming the conductor layer is not particularly limited, but it is possible to use either the electroless plating method or electroplating method. From the viewpoint of being able to form a conductor layer with a good adhesion, it is possible to use the electroless plating method in the same way as the method of forming a metal plating as the conductor layer.

Next, after the inside wall surfaces of the via holes are formed with a conductor layer, the metal foil is formed with a resist pattern for plating and further wet plating such as electroplating is used to grow a plating (thickening plating), then the resist is removed and the metal foil is further etched to pattern it and form a conductor layer. Therefore, the conductor layer formed by this method is comprised of a patterned metal foil and plating which is grown on this.

By using the above obtained multilayer circuit board as the board for producing the above-mentioned laminate, hot press bonding the above-mentioned shaped article or composite shaped article, and curing the same to form the electrical insulating layer and further forming a conductor layer on this in accordance with the above method, then repeating these steps, it is possible to form a further multilayer structure and thereby possible to obtain the desired multilayer circuit board.

The thus obtained composite of the present invention (and multilayer circuit board constituting one example of the composite of the present invention) has an electrical insulating layer comprised of the multilayer curable resin film of the present invention (cured product of the present invention). The electrical insulating layer is excellent in electrical characteristics and mechanical characteristics and further enables the formation of plated conductors by electroless plating with a high adhesion. Therefore, the multilayer circuit board of the present invention can be suitably used for various applications.

(Board for Electronic Material)

The board for electronic material of the present invention is comprised of the cured product or composite of the above-mentioned present invention. The board for electronic material of the present invention comprised of the cured product or composite of the present invention can be suitably used for various electronic equipment such as a mobile phone, PHS, notebook type PC, PEA (personal digital assistant), mobile television phone, personal computer, super computer, server, router, liquid crystal projector, engineering workstation (EWS), pager, word processor, television, viewfinder type or monitor direct viewing type video tape recorder, electronic notebook, electronic desktop computer, car navigation system, POP terminal, and device provided with a touch panel.

### Examples

Below, examples and comparative examples will be given to explain the present invention more specifically. Note that, in the examples, “parts” and “%” are based on weight unless indicated otherwise. The various physical properties were evaluated by the following methods.

(1) Number Average Molecular Weight (Mn) and Weight Average Molecule Weight (Mw) of Polymer

Using tetrahydrofuran as a development solvent, gel permeation chromatography (GPC) was used to perform measurement. The value was found converted to polystyrene.

(2) Hydrogenation Rate of Alicyclic Olefin Polymer

The ratio of the number of moles of hydrogenated unsaturated bonds with respect to the number of moles of unsaturated bonds in the polymer before hydrogenation was found by measurement of the spectrum by ¹H-NMR at 400 MHz. This was made the hydrogenation rate.

(3) Content of Monomer Units Having Carboxylic Acid Anhydride Group in Alicyclic Olefin Polymer

The ratio of the number of moles of the monomer units having a carboxylic anhydride group with respect to the number of moles of the total monomer units in the polymer was found by measurement of the spectrum by ¹H-NMR at 400 MHz. This was made the content of monomer units having a carboxylic anhydride group of the polymer.

(4) Dielectric Constant

A width 2.0 mm, length 80 Ian, thickness 40 μm piece was cut out from a film shaped cured product of the first curable resin composition and measured for dielectric constant at 10 GHz using a resonant cavity perturbation method dielectric constant measurement apparatus.

(5) Dielectric Tangent

A width 2.0 mm, length 80 mm, thickness 40 μm piece was cut out from a film shaped cured product of the first curable resin composition and measured for dielectric tangent at 10 GHz using a resonant cavity perturbation method dielectric constant measurement apparatus.

(6) Tensile Strength, Tensile Elasticity, Elongation at Break (Mechanical Characteristics)

The laminate cured product was measured for tensile strength, tensile elasticity, and elongation at break using a tensile test apparatus under conditions of a tensile speed of 5 mm/min.

(7) Plating Adhesion

The pulloff strength (peel strength) of the plateable layer obtained by curing the second resin layer (layer comprised of second curable resin composition) in the multilayer printed circuit board and the copper plating layer was measured based on JIS 06481. The following criteria were used for evaluation of the plating adhesion.

Good: peel strength of 5N/cm or more

Poor: peel strength of less than 5N/cm

(8) Adhesion of Copper Foil

The surface of a thickness 35 μm electrolytic copper foil was etched by an etchant (product name “CZ-8101”, made by MEC) by 0.5 μm. On the etched surface of the obtained electrolytic copper foil, a film shaped article was stacked and hot press bonded by a vacuum laminator under conditions of a vacuum degree of 1 kPa or less, 90° C., 30 seconds, and a pressure of 0.7 MPa. Next, the support was peeled off from the film shaped article. On the surface, a glass epoxy copper-clad laminate (FR-4) etched by the above etchant by about 2 μm was superposed at the etched surface and hot press bonded by a vacuum laminator under the same conditions as the above. The above obtained composite shaped article was raised in temperature in an oven under a flow of nitrogen to 195° C. over 60 minutes, then was heated under a flow of nitrogen at 195° C. for 15 minutes to obtain a laminate cured product. The peel strength of the electrolytic copper foil from the obtained laminate cured product was measured based on JIS C6481. The following criteria were used for evaluation of the adhesion.

Good: peel strength of 4N/cm or more

Poor: peel strength of less than 4N/cm

### Synthesis Example 1

3.47 parts of a diaminotriazine structure-containing silane compound represented by the following formula (18) and 21.2 parts of a norbornene structure-containing silane compound represented by the following formula (19) were used. The method of hydrolysis of alkoxysilane and a dehydration condensation reaction was used to hydrolyze these and cause dehydration condensation of the obtained hydrolyzate whereby a condensate of a diaminotriazine structure-containing silane compound/norbornene structure-containing silane compound was obtained. The obtained copolymer was measured for ratio of composition by elemental analysis, whereupon the units based on a diaminotriazine structure-containing silane compound=10 mol % and the units based on a norbornene structure-containing silane compound=90 mol %. Further, the weight average molecule weight was 942.

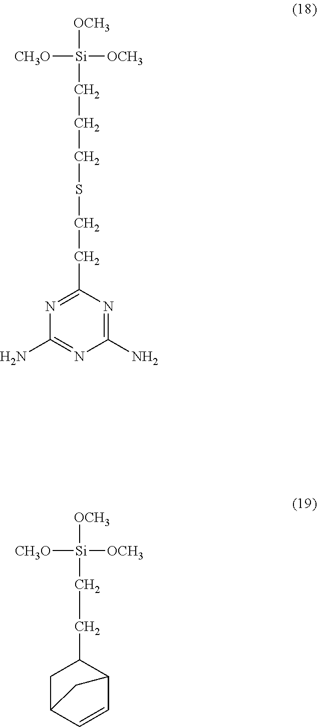

### Synthesis Example 2

As the first stage of polymerization, 35 mole parts of 5-ethylidene-bicyclo[2.2.1]hept-2-ene, 0.9 mole part of 1-hexene, 340 mole parts of anisole, and 0.005 mole part of a ruthenium-based polymerization catalyst comprised of 4-acetoxybenzylidene(dichloro) (4,5-dibromo-1,3-dimesityl-4-imidazolin-2-ylidene) (tricyclohexylphosphine) ruthenium (C1063, made by Wako Pure Chemical Industries) were charged into a nitrogen substituted pressure-resistant reactor and stirred at 80° C. for 30 minutes to perform a polymerization reaction to obtain a solution of a norbornene-based ring opened polymer.

Next, as a second stage of polymerization, to the solution obtained at the first stage of polymerization, 45 mole parts of tetracyclo[6.5.0.1^{2,5}.0^{8,13}]dodeca-3,8,10,12-tetraene, 20 mole parts of bicyclo[2.2.1]hept-2-ene-5,6-dicarboxylic anhydride, 250 mole parts of anisole, and 0.01 mole part of a ruthenium-based polymerization catalyst comprised of 4-acetoxybenzylidene(dichloro) (4,5-dibromo-1,3-dimesityl-4-imidazolin-2-ylidene) (tricyclohexylphosphine) ruthenium (C1063, made by Wako Pure Chemical Industries) were added. These were stirred for a polymerization reaction at 80° C. for 1.5 hours to obtain a solution of a norbornene-based ring opened polymer. This solution was measured by gas chromatography, whereupon it was confirmed that substantially no monomer remained. The polymerization conversion rate was 99% or more.

Next, an autoclave equipped with a stirrer and with the inside replaced by nitrogen was charged with a solution of the obtained ring-opened polymer. 0.03 mol part of C1063 was added, then the mixture was stirred at 150° C. at a hydrogen pressure of 7 MPa and stirred for 5 hours to perform a hydrogenation reaction to obtain a solution of a hydrogenate of a norbornene-based ring-opened polymer comprising the alicyclic olefin polymer (1). The alicyclic olefin polymer (1) had a weight average molecule weight of 60,000, a number average molecular weight of 30,000, and a molecular weight distribution of 2. Further, the hydrogenation rate was 95%, while the content of the repeating units having a carboxylic anhydride group was 20 mol %. The solid content concentration of the solution of the alicyclic olefin polymer (1) was 22%.

### Example 1

(First Curable Resin Composition)

117 parts of polyphenylene ether oligomer (A1) comprised of a both ends styryl group-modified polyphenylene ether oligomer (product name “OPE-2St1200”, made by Mitsubishi Gas Chemical, reaction product of 2,2′,3,3′,5,5′-hexamethylbiphenyl-4,4′-diol/2,6-dimethylphenol polycondensate and chloromethylstyrene, number average molecular weight (Mn)=1,200, 60% toluene solution) (70 parts as both ends styryl group-modified polyphenylene ether oligomer), 30 parts of an elastomer (A3) comprised of a styrene-isoprene-styrene block copolymer (product name “Quintac3390”, made by Zeon Corporation, weight average molecule weight (Mw)=120,000, styrene unit content=48%), 1.1 parts of a triazine structure-containing polymer (A4) comprised of a condensate of a diaminotriazine structure-containing silane compound/norbornene structure-containing silane compound obtained in the above Synthesis Example 1, 0.07 part of a curing agent (A2) comprised of dicumyl peroxide (product name “Parkerdox BC-FF”, made by Kayaku Akzo), and 52 parts of toluene were mixed and stirred by a planetary type stirrer for 5 minutes to obtain a varnish of the first curable resin composition.

(Preparation of Film Shaped Article of First Curable Resin Composition)

Next, the above obtained varnish of the first curable resin composition was coated using a die coater on a polyethylene terephthalate film of a vertical 300 mm×horizontal 300 mm size and thickness of 38 μm having a release agent layer on its surface (support: Unipeel TR6, made by Unitika), next, this was dried in a nitrogen atmosphere at 80° C. for 10 minutes to obtain a thickness 43 μm film shaped article of the first curable resin composition on a support.

(Preparation of Film-Shaped Cured Product of First Curable Resin Composition)

Next, to a thickness 10 μm copper foil, a small piece of the film shaped article of the first curable resin composition obtained above was superposed in a state with support attached so that the first curable resin composition became the inside, a vacuum laminator provided with heat resistant rubber press plates at the top and bottom was used to hot press bond this at a vacuum of 200 Pa, a temperature of 110° C., and a pressure of 0.1 MPa for 60 seconds to laminate it, the laminate was raised in temperature under a flow of nitrogen to 195° C. over 60 minutes, then this was cured by heating in a flow of nitrogen at 195° C. over 15 minutes. After curing, the copper foil-clad cured resin was cut out, the support was peeled off, and the copper foil was dissolved in 1 mol/liter of ammonium persulfate aqueous solution to obtain film-shaped cured product of the first curable resin composition. The obtained film-shaped cured product of the first curable resin composition was used in accordance with the above-mentioned methods to evaluate and measure the dielectric constant, dielectric tangent, and adhesion of the copper foil. The results are shown in Table 1.

(Second Curable Resin Composition)

454 parts of a solution of an alicyclic olefin polymer (B1) having a polar group comprised of the alicyclic olefin polymer (1) obtained in Synthesis Example 2 (100 parts converted to alicyclic olefin polymer (1)), 36 parts of a curing agent (B2) comprised of a polyvalent epoxy compound having a dicyclopentadiene structure (product name “Epiclon HP7200L”, made by DIC, “Epiclon” is a registered trademark), 24.5 parts of an inorganic filler (B3) comprised of silica (product name “Admafine SO-C1”, made by Admatechs, average particle size 0.25 μm, “Admafine” is a registered trademark), 1 part of an antiaging agent comprised of tris(3,5-di-t-butyl-4-hydroxybenzyl)isocyanurate (product name “Irganox (registered trademark) 3114”, made by BASF), 0.5 part of a UV absorbent comprised of 2-[2-hydroxy-3,5-bis(α,α-dimethylbenzyl)phenyl]-2H-benzotriazole, and 0.5 part of a curing accelerator comprised of 1-benzyl-2-phenylimidazole were mixed with anisole to a concentration of the compounding agents of 16% to thereby obtain a varnish of the second curable resin composition.

(Preparation of Multilayer Curable Resin Film)

The above obtained varnish of the second curable resin composition was coated on a thickness 38 urn polyethylene terephthalate film (support) by a wire bar, then was made to dry in a nitrogen atmosphere at 80° C. for 10 minutes to obtain a supported film famed with a thickness 3 μm second resin layer (plateable layer) comprised of the uncured second curable resin composition.

Next, the surface of the supported film on which the second resin layer comprised of the second curable resin composition was formed was coated with the above obtained varnish of the first curable resin composition using a doctor blade (made by Tester Sangyo) and auto film applicator (made by Tester Sangyo), then was made to dry in a nitrogen atmosphere at 80° C. for 10 minutes to obtain a multilayer curable resin film formed with a total thickness 40 μm of a second resin layer (plateable layer) and first resin layer (binder layer) with support. The multilayer curable resin film with support was formed from the support, second resin layer comprised of the second curable resin composition, and first resin layer comprised of the first curable resin composition in that order.

(Preparation of Laminate Cured Product)

Next, separate from the above, a varnish including a glass filler and halogen-free epoxy compound was impregnated in glass fiber to obtain a core material. On the surfaces, sheets of thickness 18 μm copper were bonded to prepare a thickness 0.8 mm, 150 mm square (vertical 150 mm and horizontal 150 mm) double-sided copper-clad board. On the surfaces of this, conductor layers which have interconnect widths and interconnect pitches of 50 μm and have thicknesses of 18 μm were formed by microetching by contact with an organic acid to obtain an internal layer board.

At the two surfaces of this internal layer board, pieces of the above obtained supported multilayer curable resin film cut to 150 mm square were bonded so that the surfaces at the sides of the first resin layer comprised of the first curable resin composition became the inside, then were pressed by primary pressing. The primary pressing was hot press-bonding by a vacuum laminator provided with heat resistant rubber press plates at the top and bottom under a reduced pressure of 200 Pa, temperature 110° C., and pressure 0.1 Mia for 90 seconds. Furthermore, a hydraulic press apparatus provided with metal press plates at the top and bottom was used for hot press-bonding at a press-bonding temperature of 110° C., 1 MPa, and 90 seconds. Next, the supports were peeled off to thereby obtain a laminate of a first resin layer comprised of the first curable resin composition, a second resin layer comprised of the second curable resin composition, and an internal layer board. Furthermore, the laminate was raised in temperature under a flow of nitrogen to 195° C. over 60 minutes, then the first resin layer and second resin layer were heated 195° C. for 15 minutes to make them cure to form electrical insulating layers on the internal layer board.

(Swelling Treatment Step)

The obtained laminate cured product was dipped while shaking in a 60° C. aqueous solution which was prepared to contain a swelling solution (“Swelling Dip Securiganth P”, made by Atotech, “Securiganth” is a registered trademark) 500 ml/liter and sodium hydroxide 3 g/liter for 15 minutes, then was rinsed.

(Oxidizing Treatment Step)

Next, the laminate cured product was dipped while shaking in an 80° C. aqueous solution which was prepared to contain an aqueous solution of permanganate (“Concentrate Compact CP”, made by Atotech) 500 ml/liter and a concentration of sodium hydroxide of 40 g/liter for 20 minutes, then was rinsed.

(Neutralizing/Reduction Treatment Step)

Next, the laminate cured product was dipped in a 40° C. aqueous solution which was prepared to contain an aqueous solution of hydroxylamine sulfate (“Reduction Securiganth P 500”, made by Atotech, “Securiganth” is a registered trademark) 100 ml/liter and sulfuric acid 35 ml/liter for 5 minutes to neutralize and reduce it, then was rinsed.

(Cleaner/Conditioner Step)

Next, the laminate cured product was dipped in a 50° C. aqueous solution which was prepared to contain a cleaner/conditioner aqueous solution (“Alcup MCC-6-A”, made by Uyemura & Co., Ltd. “Alcup” is a registered trademark) of a concentration of 50 ml/liter for 5 minutes to treat it with the cleaner and conditioner. Next, the laminate was dipped in 40° C. rinsing water for 1 minute, then was rinsed.

(Soft Etching Step)

Next, the laminate cured product was dipped in an aqueous solution which was prepared to contain a sulfuric acid concentration of 100 g/liter and sodium persulfate of 100 g/liter for 2 minutes to be soft etched, then was rinsed.

(Pickling Step)

Next, the laminate cured product was dipped in an aqueous solution which was prepared to contain a sulfuric acid concentration of 100 g/liter for 1 minute to be pickled, then was rinsed.

(Catalyst Imparting Step)

Next, the laminate cured product was dipped in a 60° C. Pd salt-containing plating catalyst aqueous solution which was prepared to contain Alcup Activator MAT-1-A (product name, made by Uyemura & Co., Ltd. “Alcup” is a registered trademark) 200 ml/liter, Alcup Activator MAT-1-B (product name, made by Uyemura & Co., Ltd. “Alcup” is a registered trademark) 30 ml/liter, and sodium hydroxide 0.35 g/liter for 5 minutes, then was rinsed.

(Activation Step)

Next, the laminate cured product was dipped in an aqueous solution which was prepared to contain Alcup Reducer MAB-4-A (product name, made by Uyemura & Co., “Alcup” is a registered trademark) 20 ml/liter and Alcup Reducer MAB-4-B (product name, made by Uyemura & Co., Ltd. “Alcup” is a registered trademark) 200 ml/liter at 35° C. for 3 minutes to reduce the plating catalyst, then was rinsed.

(Accelerator Treatment Step)

Next, the laminate cured product was dipped in an aqueous solution which was prepared to contain Alcup Accelerator MAL-3-A (product name, made by Uyemura & Co., Ltd. “Alcup” is a registered trademark) 50 ml/liter at 25° C. for 1 minute.

(Electroless Plating Step)

The thus obtained laminate was dipped in an electroless copper plating solution which was prepared to contain Thru-Cup PEA-6-A (product name, made by Uyemura & Co., Ltd. “Thru-Cup” is a registered trademark) 100 ml/liter, Thru-Cup PEA-6-B-2X (product name, made by Uyemura & Co. Ltd.) 50 ml/liter, Thru-Cup PEA-6-C (product name, made by Uyemura & Co. Ltd.) 14 ml/liter, Thru-Cup PEA-6-D (product name, made by Uyemura & Co. Ltd.) 15 ml/liter, Thru-Cup PEA-6-E (product name, made by Uyemura & Co. Ltd.) 50 ml/liter, and 37% formalin aqueous solution 5 ml/liter, while blowing in air, at a temperature of 36° C. for 20 minutes for electroless copper plating so as to form an electroless plating film on the laminate surface (surface of second resin layer comprised of second curable resin composition).

Next, the laminate cured product formed with the electroless plating coating was dipped in a rustproofing solution prepared including 10 ml/liter of AT-21 (product name, made by Uyemura) at room temperature for 1 minute, then was rinsed. Furthermore, this was dried to prepare a rustproofed laminate cured product. This rustproofed laminate cured product was annealed in an air atmosphere at 150° C. for 30 minutes.

(Electroplating Step)

The annealed laminate cured product was electroplated with copper to form a thickness 30 μm electroplated copper film. Next, the laminate cured product was heat treated at 180° C. for 60 minutes to thereby obtain a double-sided two-layer multilayer printed circuit board comprised of a laminate cured product on which a conductor layer comprised of the metal thin film layer and electroplated copper film are formed. Further, the thus obtained multilayer printed circuit board was used to evaluate the plating adhesion according to the above method.

### Example 2

When preparing the first curable resin composition, except for further mixing in 100 parts of surface-treated silica (product name “SFP-20M”, made by Denka, average particle size 0.3 μm, methacryl silane coupling agent-treated product) and changing the amount of toluene from 100 parts to 48 parts, the same procedure was followed as in Example 1 to obtain a varnish of the first curable resin composition, a film-shaped cured product of the first curable resin composition, a varnish of the second curable resin composition, a multilayer curable resin film, a laminate cured product, and a multilayer printed circuit board and the same procedure was followed to measure and evaluate them. The results are shown in Table 1.

### Example 3

When preparing the first curable resin composition, except for not mixing in the condensate of the diaminotriazine structure-containing silane compound/norbornene structure-containing silane compound obtained in the above Synthesis Example 1, the same procedure was followed as in Example 2 to obtain a varnish of the first curable resin composition, film-shaped cured product of the first curable resin composition, varnish of the second curable resin composition, multilayer curable resin film, laminate cured product, and multilayer printed circuit board and the same procedure was followed to measure and evaluate them. The results are shown in Table 1.

### Comparative Example 1

When preparing the first curable resin composition, except for not mixing in the condensate of the diaminotriazine structure-containing silane compound/norbornene structure-containing silane compound obtained in the above Synthesis Example 1, the same procedure was followed as in Example 1 to obtain a varnish of the first curable resin composition and obtain a film-shaped cured product of the first curable resin composition and the same procedure was followed to measure and evaluate them. The results are shown in Table 1.

Further, in Comparative Example 1, the second curable resin composition was not used. The varnish of the first curable resin composition obtained above was directly coated by a doctor blade (made by Tester Sangyo) and an auto film applicator (made by Tester Sangyo) on a thickness 38 μm polyethylene terephthalate film (support), then was made to dry in a nitrogen atmosphere at 80° C. for 10 minutes to obtain a curable resin film with support in which a first resin layer was formed with a total thickness of 38 μm. Except for using the thus obtained curable resin film, the same procedure was followed as in Example 1 to obtain a laminate cured product and multilayer printed circuit board and the same procedure was followed to measure and evaluate them. That is, in Comparative Example 1, a second resin layer comprised of the second curable resin composition was not formed. A curable resin film of a single layer comprised of only the first resin layer was obtained. This was used to obtain a laminate cured product and multilayer printed circuit board. These were measured and evaluated. The results are shown in Table 1.

Table 1

TABLE 1

| | | | | Compar- |
|---|---|---|---|---|
| | | | | ative |
| | Example | | | Example |
| | 1 | 2 | 3 | 1 |
| Composition of first curable | | | | |
| resin compositon (parts) | | | | |
| both ends styryl group-modified | 70 | 70 | 70 | 70 |
| polyphenylene ether oligomer | | | | |
| Styrene-isoprene-styrene | 30 | 30 | 30 | 30 |
| bock copolymer | | | | |
| Condensate of | 1.1 | 1.1 | — | — |
| diaminotriazine structure- | | | | |
| containing silane compound/ | | | | |
| norbomene structure- | | | | |
| containing silane compound | | | | |
| Dicumyl peroxide | 0.07 | 0.07 | 0.07 | 0.07 |
| Surface-treated silica | — | 100 | 100 | — |
| Formation of second resin | Yes | Yes | Yes | No |
| layer comprised of | | | | |
| socond curable resin | | | | |
| composition | | | | |
| Results of evaluation | | | | |
| Dielectric constant (10 GHz) | 2.4 | 2.6 | 2.7 | 2.4 |
| Dielectric tangent (10 GHz) | 0.002 | 0.003 | 0.002 | 0.002 |
| Tensile strength [MPa] | 53 | 55 | 53 | 52 |
| Tensile elasticity [GPa] | 2.0 | 3.4 | 4.0 | 1.7 |
| Elongation at break [%] | 5.0 | 2.3 | 1.8 | 5.4 |
| Peeling strength of copper | Good | Good | Good | Poor |
| plating layer | | | | |
| Peeling strength of copper foil | Good | Good | Poor | Poor |

As shown in Table 1, the electrical insulating layer obtained using a multilayer curable resin film of the present invention is excellent in electrical characteristics (low in dielectric constant and dielectric tangent), excellent in mechanical characteristics (tensile strength, tensile elasticity, and elongation at break), and, furthermore, excellent in plating adhesion (Examples 1 to 3).

On the other hand, when not forming the second resin layer comprised of the second curable resin composition, the obtained electrical insulating layer is poor in plating adhesion (Comparative Example 1).

1. A multilayer curable resin film comprising
a first resin layer comprising a first curable resin composition including a polyphenylene ether oligomer (A1) with an end modified by an aromatic vinyl group and a curing agent (A2) and
a second resin layer comprising a second curable resin composition including an alicyclic olefin polymer (B1) and a curing agent (B2).

2. The multilayer curable resin film according to claim 1 wherein the alicyclic olefin polymer (B1) is an alicyclic olefin polymer having a polar group.

3. The multilayer curable resin film according to claim 1 wherein the first curable resin composition further comprises an elastomer (A3).

4. The multilayer curable resin film according to claim 1 wherein the first curable resin composition further comprises a polymer (A4) having a triazine structure.

5. The multilayer curable resin film according to claim 1 wherein the second curable resin composition further comprises an inorganic filler (B3).

6. The multilayer curable resin film according to claim 1 further comprising a support film on the surface of the second resin layer at the opposite side to the surface where the first resin layer is laminated.

7. A method of production of a multilayer curable resin film according to claim 1 comprising
forming the second resin layer by coating, spraying, or flow casting the second curable resin composition on a substrate and
forming the first resin layer by coating, spraying, or flow casting the first curable resin composition on the second resin layer.

8. A method of production of a multilayer curable resin film according to claim 1 comprising
forming the first resin layer by coating, spraying, or flow casting the first curable resin composition on a substrate,
forming the second resin layer by coating, spraying, or flow casting the second curable resin composition on another substrate, and
laminating the respectively formed first resin layer and second resin layer on separate substrates.

9. A prepreg comprising a multilayer curable resin film according to claim 1 including a fiber substrate.

10. A laminate obtained by laminating a multilayer curable resin film according to claim 1 on a substrate.

11. A cured product obtained by curing a multilayer curable resin film according to claim 1.

12. A composite obtained by forming a conductor layer on a surface of a cured product according to claim 11.

13. A multilayer circuit board comprising
a cured product according to claim 11 and
a board having an electrical insulating layer and formed with a conductor circuit layer on one or both surfaces of the electrical insulating layer.

14. A method of production of a multilayer circuit board comprising
laminating a multilayer curable resin film according to claim 6 on a board having an electrical insulating layer and formed with a conductor circuit layer on one or both surfaces of the electrical insulating layer so that the board and the first resin layer of the multilayer curable resin film contact each other,
curing the multilayer curable resin film to obtain a cured product,
irradiating the cured product with a laser to form a via hole or through hole,
peeling off the support film, and
plating the surfaces of the via hole or through hole and cured product to form a conductor layer.

15. A laminate obtained by laminating a prepreg according to claim 9 on a substrate.

16. A cured product obtained by curing a prepreg according to claim 9.

17. A composite obtained by forming a conductor layer on a surface of a cured product according to claim 16.

18. A cured product obtained by curing a laminate according to claim 10.

19. A composite obtained by forming a conductor layer on a surface of a cured product according to claim 18.
